(19) United States
(12) Patent Application Publication
(10) Pub. No.: US 2008/0117276 A1
(43) Pub. Date: May 22, 2008

(54) THERMAL HEAD AND METHOD OF MANUFACTURING THERMAL HEAD

(75) Inventors: Takaaki Murakami, Kanagawa (JP); Yasushi Hirumi, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/942,461

(22) Filed: Nov. 19, 2007

(30) Foreign Application Priority Data
Nov. 20, 2006 (JP) 2006-313645

(51) Int. Cl. B41J 2/335; C23C 16/00

(52) U.S. Cl. 347/202; 427/255.13

(57) ABSTRACT

A thermal head is disclosed. The thermal head includes a heat generating element row in which plural heat generating elements are arrayed in a main scanning direction and a glaze that stores heat generated from the respective heat generating elements. The thermal head records an image on a recording medium by causing the respective heat generating elements to generate heat while conveying the recording medium in a sub-scanning direction. A plurality of the heat generating element rows are arrayed in the sub-scanning direction. The glaze includes plural convex portions arranged in the sub-scanning direction in association with the number of arrays of the heat generating element rows. The heat generating elements are arranged on upper sides of the convex portions, respectively.

### CROSS-REFERENCES TO RELATED APPLICATIONS

The present invention contains subject matter related to Japanese Patent Application JP 2006-313645 filed in the Japanese Patent Office on Nov. 20, 2006, the entire contents of which being incorporated herein by reference.

### BACKGROUND OF THE INVENTION

1. Field of the Invention

The present invention relates to a thermal head that has plural heat generating elements arrayed therein in a main scanning direction and causes, while conveying a recording medium in a sub-scanning direction, the respective heat generating elements to generate heat to record an image and the like on a recording medium and a method of manufacturing the thermal head, and, more particularly to a technique adapted to obtain a high recording quality even if high-speed recording is performed.

2. Description of the Related Art

There is known a thermal printer including a thermal head that has plural heat elements (heat generating elements) arrayed therein and a platen roller provided to be opposed to the thermal head. In such a thermal printer, the thermal head is pressed against a recording medium (a recording sheet, etc.), which is conveyed onto the platen roller, via an ink ribbon to record an image and the like. When a thermosensitive recording medium is used, the ink ribbon is unnecessary.

FIG. 21 is a schematic diagram showing a main part of a general thermal printer 10 and is a diagram showing a section in a direction perpendicular to a rotating shaft 31 of a platen roller 30.

The thermal printer 10 shown in FIG. 21 includes a line-type thermal head 20 that has plural heat elements (not shown) arrayed therein in a line shape. A recording sheet 40 is held on the platen roller 30 and moved by the rotation of the platen roller 30.

A general image recorded by the thermal printer 10 has the shape of a horizontally long rectangle. Therefore, depending on a type of the thermal printer 10, a relatively short side (a direction perpendicular to the paper surface in FIG. 21) of the image is set as the length of the thermal head 20 and as the main scanning direction taking into account manufacturing cost and the like. The thermal printer 10 records the image on the recording sheet 40 while conveying the recording sheet 40 (feeding the recording sheet 40 in a right direction on the paper surface in FIG. 21) to form a relatively long side of the image, which is set as the sub-scanning direction.

The thermal head 20 is pressed against the recording sheet 40 via an ink ribbon 50 of a rolled cloth shape rolled between two ribbon cartridges 51. The thermal head 20 has a glaze 21, which is a convex portion standing in the vertical direction and extending in the main scanning direction. Plural heat elements are provided in a line shape along a top surface of the glaze 21. Therefore, during recording, the respective heat elements of the thermal head 20 press the recording sheet 40 with a high linear pressure.

When recording is actually executed, the respective heat elements are caused to generate heat in this state. Then, when the thermal printer 10 is a thermal printer of a sublimation transfer system, dye (thermofusible ink) of the ink ribbon 50 is transferred onto the recording sheet 40 in proportion to thermal energy generated by the heat elements. When the thermal printer 10 is a thermal printer of a thermofusible transfer system, pigment (thermofusible ink) of the ink ribbon 50 containing wax as a binder melts with thermal energy generated by the heat elements and adheres to be transferred onto the recording sheet 40. Therefore, one point of the thermofusible ink transferred onto the recording sheet 40 by the heat elements is formed as one dot.

To form a two-dimensional image with such a thermal head 20 of the line type, it is necessary to move the thermal head 20 and the recording sheet 40 relatively to each other. In other words, the thermal printer 10 sequentially forms dots while feeding the recording sheet 40 in the sub-scanning direction. Then, plural dots are arranged in the sub-scanning direction and changed to be continuous sets of dots one after another and a dot line is formed. Moreover, a plurality of the dot lines are formed in the main scanning direction by the plural heat elements arrayed in the main scanning direction. As a result, a two-dimensional image can be formed over the entire recording sheet 40.

As described above, the thermal printer 10 shown in FIG. 21 records an image on the recording sheet 40 by causing the respective heat elements to generate heat while feeding the recording sheet 40 in the sub-scanning direction using the thermal head 20 of the line type that has the plural heat elements arrayed therein in the main scanning direction. The resolution (the density of the dot line) of the thermal printer 10 depends on the number of heat elements arrayed in the main scanning direction of the thermal head 20.

FIG. 22 is a plan view showing a thermal head 200 in the past.

As shown in FIG. 22, in the thermal head 200, plural heat elements h (h1, h2, h3, h4, h5, h6, etc.) are arrayed in one row in the main scanning direction. A total number of the heat elements h is 2560. Therefore, the thermal head 200 can form 2560 dots per one line in the main scanning direction of the respective heat elements h. Since the resolution of the thermal head 200 is 300 DPI (dots per inch), the heat elements h are arranged side by side over 2560 dots/300 DPI=8.53 inches (216 mm).

In recent years, the thermal printer 10 (see FIG. 21) is demanded to form an image with high definition and, at the same time, at higher speed. For example, high recording speed equal to or lower than 1 microsecond per one dot is demanded of the thermal printer 10. Such improvement of recording speed, which should be called as “ultrahigh speed recording”, causes a temperature rise in the thermal head 200.

The thermal head 200, which is originally a consumable product, is deteriorated more rapidly than usual because of an excessive temperature rise in the thermal head 200 and the durable life of the thermal head 200 is extremely shortened. When the heat elements h are arrayed at high density to form an image with high definition, a heat generation property of the thermal head 200 is spoiled. As a result, a trailing track is formed regardless of the finish of recording, i.e., a so-called “tailing” occurs, because of the heat stored in the thermal head 200 and a recording quality falls.

To cope with such a problem, for example, there is known a technique for arranging the heat elements h, which are arranged in one row, in two rows and using one of the rows for preheating of the recording sheet 40 (see FIG. 21) and the ink ribbon 50 (see FIG. 21) or forming dot lines, which are sets of plural dots arranged in the sub-scanning direction, in two rows to thereby prevent an excessive temperature rise in the respective heat elements h.

For example, JP-A-10-138541 (hereinafter, Patent Document 1) discloses a thermal head including a substrate, an insulating layer covering a surface of the substrate, a part of a surface of which is swelled, and a pattern of heat elements formed on the surface in the swelled portion of the insulating layer, wherein the substrate has a common electrode that projects from the surface, pierces through the swelled portion of the insulating layer and is exposed from the surface of the insulating layer to be connected to the pattern of the heat elements and divide the pattern of the heat elements into a first heat element and a second heat element on both sides of a portion of the connection.

### SUMMARY OF the INVENTION

However, in the technique disclosed in Patent Document 1, the pattern of the heat elements is simply divided into the first heat element and the second heat element. Thus, to sufficiently transmit thermal energy generated by the respective heat elements, the thermal head has to cause the respective heat elements to excessively generate heat. As a result, temperature rises more than necessary.

FIG. 23 is a sectional view in the sub-scanning direction showing a thermal head 220 in the past in which heat elements are arrayed in two rows as in the technique disclosed in Patent Document 1.

As shown in FIG. 23, a first heat element h1a and a second heat element h1b are formed on the surface of a ridge portion 222 (the swelled portion in Patent Document 1) of a glaze 22l (the insulating layer in Patent Document 1). In the main scanning direction, heat elements h1a, h2a, and the like (heat elements h2a and the like are not shown) and heat elements h1b, h2b, and the like (heat elements h2a and the like are not shown) are arrayed.

A section of the ridge portion 222 of the glaze 22l is semicircular. A resistance material layer 224 and an aluminum layer 225 are formed on the surface of the ridge portion 222. The aluminum layer 225 is fragmented on the left and right of the top of the ridge portion 222. The resistance material 224 in this fragmented portion is formed as the first heat element h1a and the second heat element h1b. The aluminum layer 225 in the remaining portion is formed as respective electrodes “e”. Surfaces of the first heat element h1a, the second heat element h1b, and the respective electrodes “e” are coated with a protective film 226.

The glaze 22l including the ridge portion 222 is used in this way to make it possible to effectively press the ink ribbon 50 (the recording sheet 40 and the platen roller 30). As described above, in the thermal printer 10 shown in FIG. 21, the thermal head 220 nips the recording sheet 40 and the ink ribbon 50 between the glaze 22l and the platen roller 30 shown in FIG. 23 and applies predetermined pressure and heat thereto with the first heat element h1a and the second heat element h1b to record an image and the like on the recording sheet 40. Therefore, “contact” of the first heat element h1a and the second heat element h1b with the platen roller 30 via the recording sheet 40 and the ink ribbon 50 (an angle of collision of the first heat element h1a and the second heat element h1b with the platen roller 30) is demanded to be proper. The first heat element h1a and the second heat element h1b are formed on a top surface of the ridge portion 222 to improve “contact”.

However, when the first heat element h1a and the second heat element h1b are arranged on the left and right of the top of the ridge portion 222, since “contact” is deteriorated, a heat transfer rate falls. In other words, since the first heat element h1a and the second heat element h1b are arranged on both sides of the top of the ridge portion 222, although a certain degree of “contact” is obtained in both the first heat element h1a and the second heat element h1b, the “contact” is insufficient. Therefore, to perform optimum recording, it is necessary to cause the first heat element h1a and the second heat element h1b to excessively generate heat. As a result, the temperature of the thermal head 220 rises more than necessary.

Such excessive rise in the temperature of the thermal head 220 weakens the effect realized by providing the first heat element h1a and the second heat element h1b. Thus, the “contact” is insufficient for preventing the fall in a recording quality while realizing high definition and high-speed recording of a formed image. It is conceivable to shift positions of the first heat element h1a and the second heat element h1b to one side in the sub-scanning direction as a whole to arrange one of the first heat element h1a and the second heat element h1b at the top of the ridge portion 222 and secure sufficient “contact”. However, this extremely deteriorates “contact” of the other heat element. Therefore, “contact” of the first heat element h1a and the second heat element h1b with the platen roller 30 is not improved (this means that “contact” is also deteriorated by occurrence of positional deviation in a manufacturing process).

Therefore, it is desirable to make it possible to prevent excessive temperature rise of a thermal head, suppress further deterioration in the thermal head, and prevent the fall in a recording quality due to occurrence of “tailing” and the like even if high definition and high-speed recording of a formed image are realized. It is also desirable to make it possible to manufacture such a thermal head.

According to an embodiment of the present invention, there is provided a thermal head including a heat generating element row in which plural heat generating elements are arrayed in a main scanning direction and a glaze that stores heat generated from the respective heat generating elements. The thermal head records an image on a recording medium by causing the respective heat generating elements to generate heat while conveying the recording medium in a sub-scanning direction. A plurality of the heat generating element rows are arrayed in the sub-scanning direction. The glaze includes plural convex portions arranged in the sub-scanning direction in association with the number of arrays of the heat generating element rows. The heat generating elements are arranged on upper sides of the convex portions, respectively.

(Action)

According to the embodiment, the glaze includes the plural convex portions arranged in the sub-scanning direction in association with the number of arrays of the heat generating elements. The heat generating elements are arranged on the upper sides of the convex portions, respectively. Therefore, “contact” of the respective heat generating elements is improved by the respective convex portions and a heat transfer rate is improved.

According to another embodiment of the present invention, there is provided a thermal head including a heat generating element row in which plural heat generating elements are arrayed in a main scanning direction and a glaze that stores heat generated from the respective heat generating elements. The thermal head records an image on a recording medium by causing the respective heat generating elements to generate heat while conveying the recording medium in a sub-scanning direction. A plurality of the heat generating element rows are arrayed in the sub-scanning direction. The glaze is partially divided in the sub-scanning direction in association with the number of arrays of the heat generating element rows. The glaze includes plural partial ridge portions of a ridge shape in sections thereof in the sub-scanning direction. The heat generating elements are arranged on upper sides of the partial ridge portions, respectively.

(Action)

According to the embodiment, the glaze is partially divided in the sub-scanning direction in association with the number of arrays of the heat generating element rows. The glaze includes the plural partial ridge portions of a ridge shape in sections thereof in the sub-scanning direction. The heat generating elements are arranged on the upper sides of the partial ridge portions, respectively. Therefore, “contact” of the respective heat generating elements is improved by the respective partial ridge portions and a heat transfer rate is improved.

According to still another embodiment of the present invention, there is provided a thermal head including a heat generating element row in which plural heat generating elements are arrayed in a main scanning direction and a glaze that stores heat generated from the respective heat generating elements. The thermal head records an image on a recording medium by causing the respective heat generating elements to generate heat while conveying the recording medium in a sub-scanning direction. A plurality of the heat generating element rows are arrayed in the sub-scanning direction. The glaze includes a ridge portion of a ridge shape in a section thereof in the sub-scanning direction and a flat portion formed at the top of the ridge portion. The heat generating elements are arranged on an upper side of the flat portion in each of the heat generating element rows.

(Action)

According to the embodiment, the glaze includes the ridge portion, the section in the sub-scanning direction of which is a ridge shape, and the flat portion formed at the top of the ridge portion. The heat generating elements are arranged on the upper side of the flat portion in each of the heat generating element rows. Therefore, “contact” of the respective heat generating elements is improved by the flat portion and a heat transfer rate is improved.

According to still another embodiment of the present invention, there is provided a thermal head including a heat generating element row in which plural heat generating elements are arrayed in a main scanning direction and a glaze that stores heat generated from the respective heat generating elements. The thermal head records an image on a recording medium by causing the respective heat generating elements to generate heat while conveying the recording medium in a sub-scanning direction. A plurality of the heat generating element rows are arrayed in the sub-scanning direction. The glaze includes plural ridge portions of a ridge shape in sections thereof in the sub-scanning direction arranged in the sub-scanning direction in association with the number of arrays of the heat generating element rows. The heat generating elements are arranged on upper sides of the ridge portions, respectively.

(Action)

According to the embodiment, the glaze includes the plural ridge portions, the sections of which in the sub-scanning direction are a ridge shape, arranged in the sub-scanning direction in association with the number of arrays of the heat generating element rows. The heat generating elements are arranged on the upper sides of the ridge portions, respectively. Therefore, “contact” of the respective heat generating elements is improved by the respective ridge portions and a heat transfer rate is improved.

According to still another embodiment of the present invention, there is provided a thermal head including a heat generating element row in which plural heat generating elements are arrayed in a main scanning direction and a glaze that stores heat generated from the respective heat generating elements. The thermal head records an image on a recording medium by causing the respective heat generating elements to generate heat while conveying the recording medium in a sub-scanning direction. A plurality of the heat generating element rows are arrayed in the sub-scanning direction. The glaze includes a flat base portion and a ridge portion of a ridge shape in a section thereof in the sub-scanning direction. The heat generating elements are separately arranged on upper sides of the base portion and the ridge portion in each of the heat generating element rows.

(Action)

According to the embodiment, the glaze includes the flat base portion and the ridge portion, the section of which in the sub-scanning direction is a ridge shape. The heat generating elements are separately arranged on the upper sides of the base portion and the ridge portion. Therefore, “contact” of the respective heat generating elements is improved by the base portion and the ridge portion and a heat transfer rate is improved.

According to still another embodiment of the present invention, there is provided a method of manufacturing a thermal head including a heat generating element row in which plural heat generating elements are arrayed in a main scanning direction and a glaze that stores heat generated from the respective heat generating elements, the thermal head recording an image on a recording medium by causing the respective heat generating elements to generate heat while conveying the recording medium in a sub-scanning direction. The method includes the steps of forming, on a substrate, the glaze having irregularities corresponding to the number of arrays of a plurality of the heat generating element rows arrayed in the sub-scanning direction, forming, on the irregularities of the glaze, the respective heat generating elements and electrodes for driving the respective heat generating elements, and coating the respective heat generating elements and the respective electrodes with a protective film.

(Action)

According to the embodiment, the method includes the steps of forming, on a substrate, the glaze having irregularities corresponding to the number of arrays of a plurality of the heat generating element rows arrayed in the sub-scanning direction, and forming, on the irregularities of the glaze, the respective heat generating elements and electrodes for driving the respective heat generating elements. Therefore, “contact” of the respective heat generating elements is improved by the irregularities of the glaze and a heat transfer rate is improved.

According to the embodiments of the present invention, “contact” of the respective heat generating elements is improved and a heat transfer rate is improved. Moreover, it is possible to manufacture a thermal head in which “contact” of the respective heat generating elements is improved and a heat transfer rate is improved. Therefore, it is possible to prevent excessive temperature rise in the thermal head even if high definition and high-speed recording of a formed image are realized. As a result, further deterioration in the thermal head is suppressed and the durable life of the thermal head is extended. Moreover, it is possible to prevent the fall in a recording quality due to occurrence of “tailing” and the like.

### BRIEF DESCRIPTION OF THE DRAWINGS

FIG. 1 is a plan view showing a thermal head according to an embodiment of the present invention;

FIG. 2 is a sectional view in a sub-scanning direction showing a thermal head according to a first embodiment of the present invention;

FIG. 3 shows sectional views in the sub-scanning direction showing a glaze forming process (step 1 to step 3) in a method of manufacturing the thermal head according to the first embodiment;

FIG. 4 shows sectional views in the sub-scanning direction showing the glaze forming process (step 4 to step 6) and a heat treatment process (step 7) following FIG. 3;

FIG. 5 shows sectional views in the sub-scanning direction showing a heat generating portion forming process (step 8 to step 10) and a protective film forming process (step 11) following FIG. 4;

FIG. 6 is a sectional view in the sub-scanning direction showing a thermal head according to a second embodiment of the present invention;

FIG. 7 shows sectional views in the sub-scanning direction showing an example of a glaze forming process (step 1 to step 4) in a method of manufacturing the thermal head according to the second embodiment;

FIG. 8 shows sectional views in the sub-scanning direction showing another example of the glaze forming process (step 1 and step 2) in the method of manufacturing the thermal head according to the second embodiment;

FIG. 9 is a sectional view in the sub-scanning direction showing a thermal head according to a third embodiment of the present invention;

FIG. 10 is a sectional view in the sub-scanning direction showing a thermal head according to a fourth embodiment of the present invention;

FIG. 11 is a sectional view in the sub-scanning direction showing a thermal head according to a fifth embodiment of the present invention;

FIG. 12 is a sectional view in the sub-scanning direction showing a thermal head according to a sixth embodiment of the present invention;

FIG. 13 is a sectional view in the sub-scanning direction showing a thermal head according to a seventh embodiment of the present invention;

FIG. 14 is a sectional view in the sub-scanning direction showing a thermal head according to an eighth embodiment of the present invention;

FIG. 15 is a sectional view in the sub-scanning direction showing a thermal head according to a ninth embodiment of the present invention;

FIG. 16 is a sectional view in the sub-scanning direction showing a thermal head according to a tenth embodiment of the present invention;

FIG. 17 is a sectional view in the sub-scanning direction showing a thermal head in according to an eleventh embodiment of the present invention;

FIG. 18 is a sectional view in the sub-scanning direction showing a thermal head according to a twelfth embodiment of the present invention;

FIG. 19 is a sectional view in the sub-scanning direction showing a thermal head according to a thirteenth embodiment of the present invention;

FIG. 20 is a sectional view in the sub-scanning direction showing a thermal head according to a fourteenth embodiment of the present invention;

FIG. 21 is a schematic diagram showing a main part of a general thermal printer;

FIG. 22 is a plan view showing a thermal head in the past; and

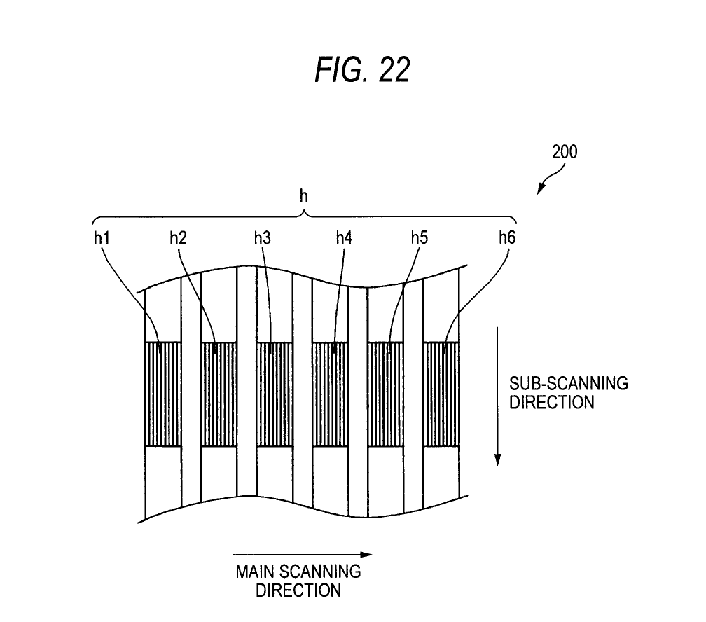

FIG. 23 is a sectional view in the sub-scanning direction showing another thermal head in the past.

### DESCRIPTION OF THE PREFERRED EMBODIMENTS

Embodiments of the present invention will be hereinafter explained in detail with reference to the accompanying drawings. In the embodiments, a heat element is equivalent to a heat generating element in the present invention. A heat element row is equivalent to a heat generating element row in the present invention.

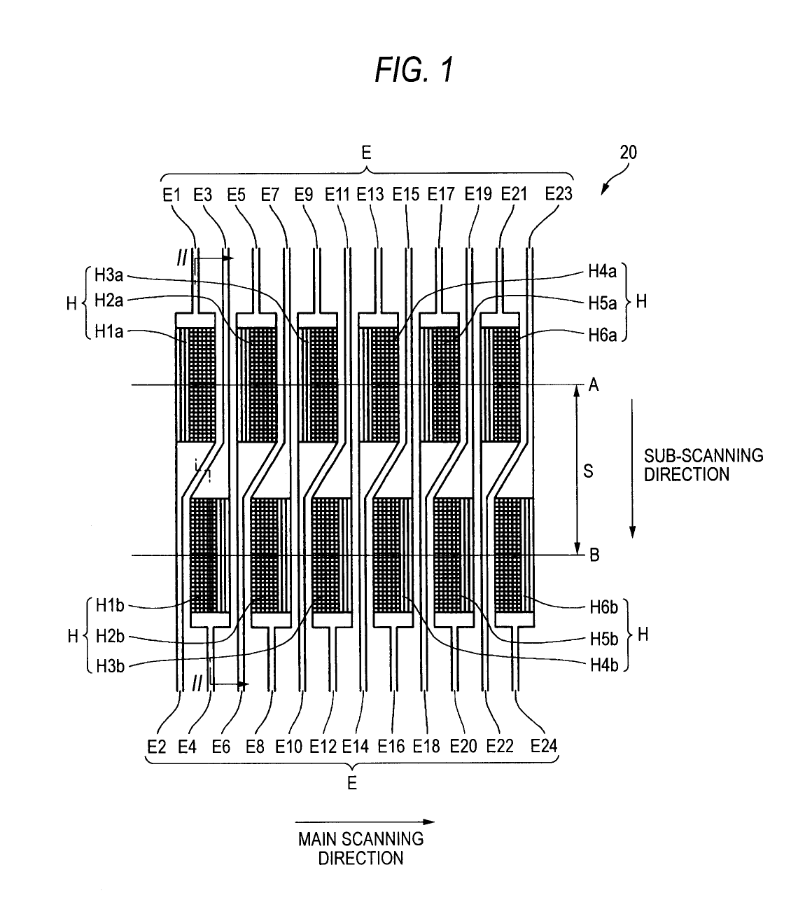

FIG. 1 is a plan view showing a thermal head 20 according to an embodiment of the present invention common to embodiments described below.

As shown in FIG. 1, heat elements H (H1a, H1b, H2a, H2b, H3a, H3b, H4a, H4b, H5a, H5b, H6a, H6b, etc.) are arrayed in the thermal head 20. The heat elements H1a, H2a, H3a, H4a, H5a, H6a, and the like are arrayed in a main scanning direction to form a heat element row Ha. The heat elements H1b, H2b, H3b, H4b, H5b, H6b, and the like are arrayed in the main scanning direction to form a heat element row Hb. A size of the respective heat elements H is 55 μm×170 μm.

The respective heat elements H are connected to electrodes E (E1, E2, E3, E4, E5, E6, E7, E8, E9, E10, E11, E12, E13, E14, E15, E16, E17, E18, E19, E20, E21, E22, E23, E24, etc.) at both ends thereof. Pairs of heat elements H1a and H1b, H2a and H2b, H3a and H3b, H4a and H4b, H5a and H5b, H6a and H6b, and the like are connected to pairs of electrodes arrayed adjacent to each other E1 and E3 (E2 and E4), E5 and E7 (E6 and E8), E9 and E11 (E10 and E12), E13 and E15 (E14 and E16), E17 and E19 (E18 and E20), E21 and E23 (E22 and E24), and the like. The pairs of heat elements have overlapping portions (indicated by halftone dot meshing portions shown in FIG. 1) and non-overlapping portions (with respect to the main scanning direction) in a sub-scanning direction. The respective electrodes E are wired in the non-overlapping portions.

Therefore, the heat element row Ha and the heat element row Hb arrayed in two rows in the sub-scanning direction do not need extra spaces for wiring the respective electrodes E. It is possible to reduce intervals in the main scanning direction (pitches among the heat elements H1a, H2a, H3a, H4a, H5a, H6a, and the like and pitches among the heat elements H1b, H2b, H3b, H4b, H5b, H6b, and the like). Thus, the heat element row Ha and the heat element row Hb are formed with high density. In the thermal head 20 according to this embodiment, the width of the respective electrodes E and a space between the respective electrodes E and the respective heat elements H are 10 μm, respectively. The resolution of the thermal head 20 is 600 DPI. In the heat element row Ha and the heat element row Hb, 5120 heat elements H1a, H2a, H3a, H4a, H5a, H6a, and the like and 5120 heat elements H1b, H2b, H3b, H4b, H5b, H6b, and the like are arrayed, respectively.

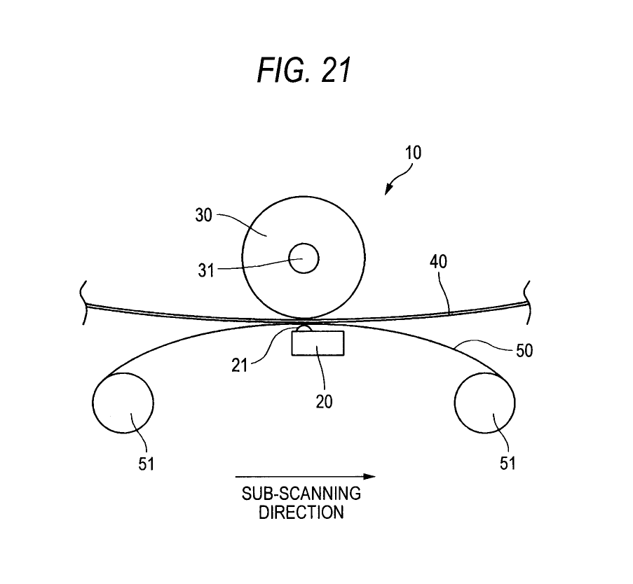

The pairs of heat elements H1a and H1b, H2a and H2b, H3a and H3b, H4a and H4b, H5a and H5b, H6a and H6b, and the like opposed to each other between the heat element row Ha and the heat element row Hb have overlapping portions (indicated by halftone dot meshing portions shown in FIG. 1) (with respect to the main scanning direction) in the sub-scanning direction. The pairs of heat elements are arrayed not to form overlapping portions with the other heat elements H (e.g., in the case of the heat element H1a, with the heat elements H2b to H6b excluding the heat element H1b) (with respect to the main scanning direction) in the sub-scanning direction. Therefore, dot lines arranged in the main scanning direction (plural sets of dots arranged in the sub-scanning direction on a recording sheet 40 (see FIG. 21)) can be formed by the pairs of heat elements H1a and H1b, H2a and H2b, H3a and H3b, H4a and H4b, H5a and H5b, H6a and H6b, and the like opposed to each other between the heat element row Ha and the heat element row Hb. Moreover, the formation of the dots in an identical dot line (identical or different dots in the sub-scanning direction) can be shared by the heat element rows Ha and Hb.

Furthermore, the heat element row Ha and the heat element row Hb are arranged to be shifted by length S in the sub-scanning direction. Therefore, there is a space S in the sub-scanning direction between a reference line A connecting the centers (indicated by black circles) of the heat elements H1a, H2a, H3a, H4a, H5a, H6a, and the like of the heat element row Ha and a reference line B connecting the centers (indicated by black circles) of the heat elements H1b, H2b, H3b, H4b, H5b, H6b, and the like of the heat element row Hb. The space S is n (n is a natural number) times as large as a pitch of dots (hereinafter referred to as dot pitch) formed in the sub-scanning direction of the recording sheet 40 (see FIG. 21). The centers of the heat elements H indicate points where generated thermal energy is the highest.

When the space S is too large, the centers of the respective heat elements H substantially deviate from the top of a glaze 21 (see FIG. 21) and “contact” of the respective heat elements H is deteriorated and a heat transfer rate falls. The “contact” has a close relation with a diameter and rubber hardness of the platen roller 30 in use (see FIG. 21), a pressing force of the thermal head 20, and the like. In the thermal head 20 according to this embodiment, the space S is set to be three times as large as the dot pitch to secure appropriate “contact”. Therefore, when the dot pitch is 85 μm, the space S is 255 μm calculated from 85 μm×n (n=3).

In the thermal head 20 according to this embodiment shown in FIG. 1, “contact” of the respective heat elements H is improved and a heat transfer rate is improved by a sectional shape in the sub-scanning direction of the glaze 21 (see FIG. 21).

Thermal heads 20 including glazes 21 with improved “contact” of the respective heat elements H according to embodiments of the present invention are explained below on the basis of sectional views in the sub-scanning direction. Sections in the sub-scanning direction are sections along the sub-scanning direction of the respective heat elements H formed in the glaze 21 and are sections (C-C sections) that traverse the heat element H1a and the heat element H1b opposed to each other in the sub-scanning direction. The plan view (FIG. 1) is identical for the respective embodiments. A section in the sub-scanning direction of the glaze 21 continuously extends in an identical shape in the main scanning direction.

### First Embodiment

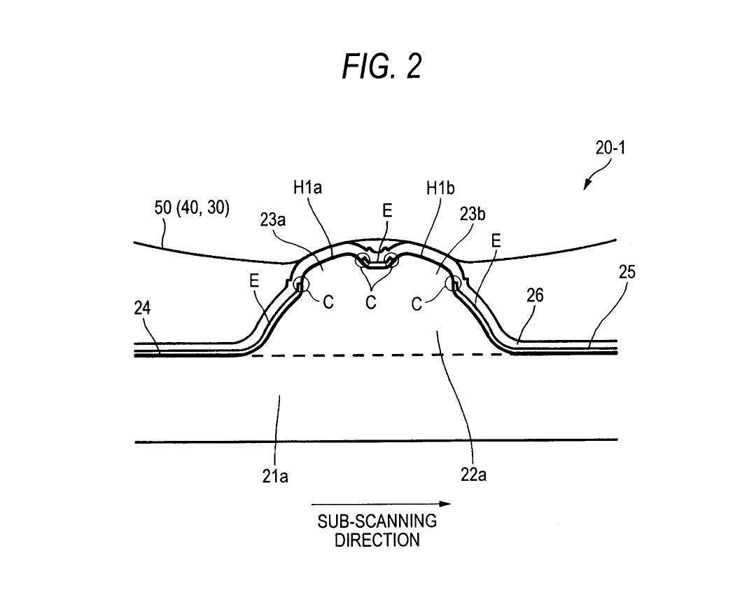

FIG. 2 is a sectional view in the sub-scanning direction showing a thermal head 20-1 according to a first embodiment of the present invention.

As shown in FIG. 2, in the thermal head 20-1 according to the first embodiment, a glaze 21a made of glass is formed on a substrate of alumina ceramics (not shown). The glaze 21a includes a ridge portion 22a of a ridge shape (a semicircular shape) in a section in the sub-scanning direction. On an upper side of the ridge portion 22a, plural (two) convex portions 23a and 23b arranged in the sub-scanning direction in association with the number of arrays (two rows) of the heat element row Ha and the heat element row Hb (see FIG. 1) are formed.

A resistance material layer 24 and an aluminum layer 25 are sequentially stacked on upper sides of the convex portions 23a and 23b to form the heat element H1a, the heat element H1b, and the respective electrodes E. A protective film 26 is formed to cover the heat element H1a, the heat element H1b, and the respective electrodes E. The heat element H1a, the heat element H1b, and the respective electrodes E are formed as a pattern as shown in FIG. 1 in plan view.

A sectional shape in the sub-scanning direction of the ridge portion 22a is a semi-arcuate shape convex upward at least near a top most portion of the ridge portion 22a and is formed of a gentle curved line. On both sides of the top most portion of the ridge portion 22a, two convex portions 23a and 23b further convex upward and flat at the tops are symmetrically formed. The two heat elements H1a and H1b are arranged on upper sides of the flat tops of the convex portion 23a and the convex portion 23b, respectively. The centers in the sub-scanning direction of the heat element H1a and the heat element H1b are located in the centers of the tops of the convex portion 23a and the convex portion 23b.

The heat element H1a and the heat element H1b are connected to the electrodes E at both ends thereof. Electrode connecting portions C (indicated by white circles) opposed to each other in the sub-scanning direction of the heat element H1a and the heat element H1b are located in positions lower than highest portions of the heat element H1a and the heat element H1b. Therefore, an edge portion of the protective film 26 between the heat element H1a and the heat element H1b does not come into contact with the ink ribbon 50 (the recording sheet 40 and the platen roller 30).

Since both shoulder portions of the convex portion 23a and the convex portion 23b are formed of gentle curved lines, breakage and the like of the respective electrodes E wired to pass on the upper sides of the convex portion 23a and the convex portion 23b less easily occur. Film strain and the like in forming the protective film 26 are eased.

As described above, the thermal head 20-1 according to the first embodiment is semicircular in the section in the sub-scanning direction of the ridge portion 22a. The convex portion 23a and the convex portion 23b are formed on the upper side of the ridge portion 22a. The heat element H1a and the heat element H1b are arranged on the upper sides of the convex portion 23a and the convex portion 23b, respectively. Therefore, “contact” of the heat element H1a and the heat element H1b with the platen roller 30 is improved. Satisfactory “contact” with the recording sheet 40 and the ink ribbon 50 nipped and pressed between the heat elements H1a and H1b and the platen roller 30 is realized. As a result, even if high definition and high-speed recording of a formed image are realized, it is possible to prevent excessive temperature rise in the thermal head 20-1, suppress further deterioration in the thermal head 20-1, and prevent the fall in a recording quality due to occurrence of “tailing” or the like.

The centers in the sub-scanning direction of the heat element H1a and the heat element H1b may be set in positions shifted closer to the center between the heat elements than the centers of the tops of the convex portion 23a and the convex portion 23b. Consequently, “contact” of the heat element H1a and the heat element H1b can be further improved. However, it is preferable to set an amount of the shift in a range in which the edge portion of the protective film 26 formed on the upper side of the electrode connecting portions C does not project upward.

A method of manufacturing the thermal head 20-1 according to the first embodiment shown in FIG. 2 is explained.

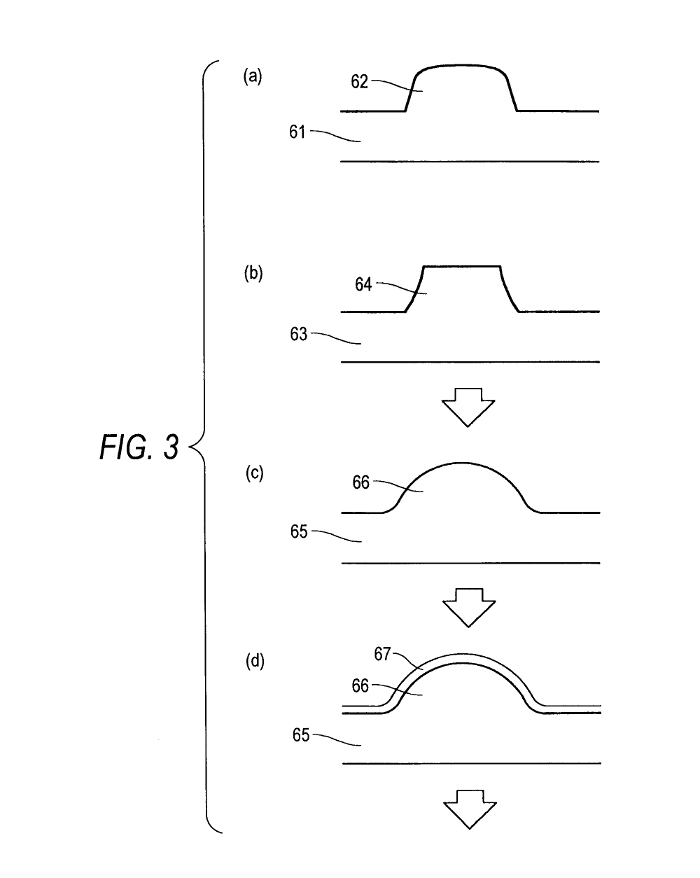

FIG. 3 shows sectional views in the sub-scanning direction showing a glaze forming process (step 1 to step 3) in the method of manufacturing the thermal head 20-1 according to the first embodiment shown in FIG. 2.

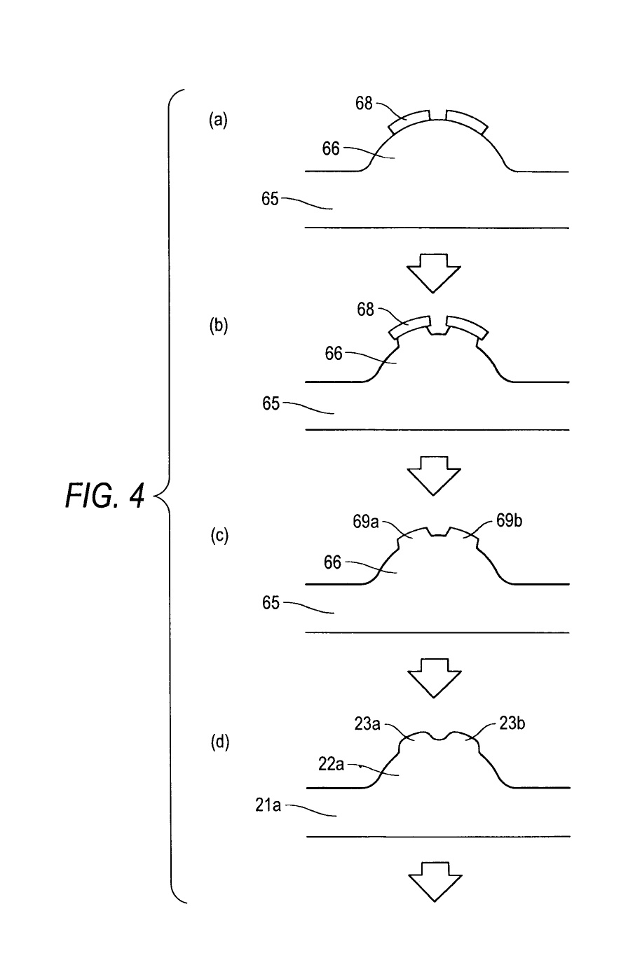

FIG. 4 shows sectional views in the sub-scanning direction showing the glaze forming process (step 4 to step 6) and a heat treatment process (step 7) following FIG. 3.

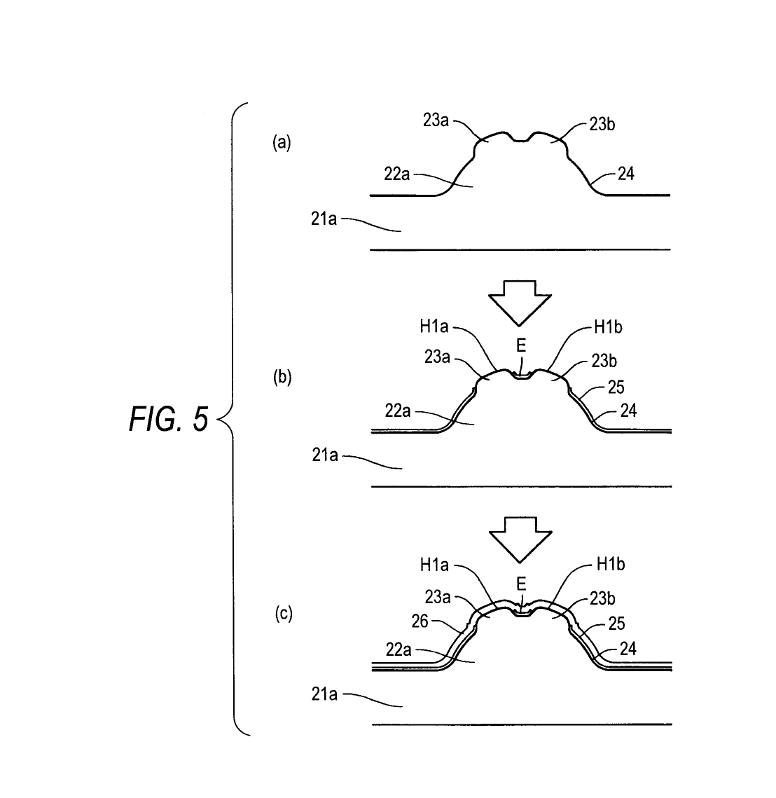

FIG. 5 shows sectional views in the sub-scanning direction showing a heat generating portion forming process (step 8 to step 10) and a protective film forming process (step 11) following FIG. 4.

To manufacture the thermal head 20-1 according to the first embodiment shown in FIG. 2, first, in step 1 (a part of the glaze forming process) shown in (a) and (b) in FIG. 3, a glass paste is formed in a predetermined shape on the substrate of aluminum ceramics (not shown) or the like. Thereafter, in step 2 (a part of the glaze forming process) shown in (c) in FIG. 3, a glass flat portion 65 and a glass ridge portion 66 are formed.

In the case of step 1 shown in (a) in FIG. 3, for example, the glass paste is formed in predetermined shapes (a glass paste 61 extending in the main scanning direction in association with the glaze 21a (see FIG. 2) and a glass paste 62 extending in the main scanning direction in association with the ridge portion 22a (see FIG. 2)) according to screen printing and drying after that. Then, in step 2 shown in (c) in FIG. 3, the glass paste 61 and the glass paste 62 are baked at a temperature of about 1200° C., whereby intentional reflow is performed in addition to the baking. A rectangular pattern of the glass pastes is deformed into an R shape to form the glass ridge portion 66 and the glass flat portion 65. After continuously creating the predetermined shapes by the screen printing of the two layers in this way, it is also possible to collectively perform baking. However, when shape stability and the like during the screen printing is taken into account, it is more satisfactory to, after forming the glass paste 61 of the flat shape according to the screen printing and the drying after that, bake the glass paste 61 at a temperature of about 1200° C. to temporarily form a portion corresponding to the glass flat portion 65 shown in (c) in FIG. 3 and, then, form the glass paste 62.

On the other hand, in the case of step 1 shown in (b) in FIG. 3, the glass paste is applied to an area covering all formation areas of the glaze 21a (see FIG. 2) and the ridge portion 22a (see FIG. 2) and with thickness including both the glaze 21a and the ridge portion 22a and dried. Concerning this area, the glass paste may be applied over an entire area of a substrate (not shown) and dried. After baking the glass paste at a temperature of about 1200° C. to form flat glass, a glass rectangular shape portion 64 and a glass flat portion 63 are formed by a removing method such as etching. Thereafter, in step 2 shown in (c) in FIG. 3, a rectangular pattern of the glass paste is deformed into an R shape by performing intentional reflow by heat treatment at a temperature of about 1200° C. to form the glass ridge portion 66 and the glass flat portion 65.

In step 3 (a part of the glaze forming process) shown in (d) in FIG. 3, a resist layer 67 is formed on at least the surface of the glass flat portion 65 including the glass ridge portion 66. In step 4 (a part of the glaze forming process) shown in (a) in FIG. 4, a predetermined resist pattern 68 is formed by performing ultraviolet exposure and development using a photo-mask having a predetermined pattern corresponding to the convex portion 23a and the convex portion 23b (see FIG. 2).

Subsequently, in step 5 (a part of the glaze forming process) shown in (b) in FIG. 4, the glass flat portion 65 and the glass ridge portion 66 corresponding to an opening of the resist pattern 68 are etched to predetermined depth by, for example, wet etching using etchant containing hydrofluoric acid. Thereafter, in step 6 (a part of the glaze forming process) shown in (c) in FIG. 4, the resist pattern 68 is peeled off to obtain the glass ridge portion 66 and the glass flat portion 65 on which a convex portion 69a and a convex portion 69b having the height of about 2 to 10 μm are formed.

In this way, a basic shape of the thermal head 20-1 (see FIG. 2) is formed in the steps up to step 6 shown in (c) in FIG. 4. However, since the convex portion 69a and the convex portion 69b are patterns left as formed by etching, the patterns have edges. Therefore, in this state, it is difficult to satisfactorily form the resistance material layer 24 (see FIG. 2) and the aluminum layer 25 (see FIG. 2) on the convex portion 69a and the convex portion 69b in a post process. Therefore, in step 7 (the heat treatment process) shown in (b) in FIG. 4, all the portions are subjected to reheating treatment at a temperature of about 800 to 850° C. to round the edges of the convex portion 69a and the convex portion 69b to form the convex portion 23a and the convex portion 23b. Then, the glaze 21a including the ridge portion 22a on which the convex portion 23a and the convex portion 23b are formed is manufactured.

When the convex portion 23a and the convex portion 23b are formed by such a method, the resist layer 67 is patterned on the glass ridge portion 66. Therefore, when ultraviolet exposure is performed using the photo-mask in step 4 shown in (a) in FIG. 4, a part of an irradiated ultraviolet ray may be transmitted through the resist layer 67 to enter the glass ridge portion 66 and cause irregular reflection inside the glass ridge portion 66 or on an upper surface of the substrate of alumina ceramics (not shown) under the glass flat portion 65. Then, a rear surface of the resist layer 67, which is originally undesirable to be exposed, is exposed by the irregularly reflected ultraviolet ray. The shape of the resist pattern 68 is disordered by an influence of the exposure. In some case, it is likely that fluctuation and deficiencies occur in the shape, the dimension, the height, and the like of the convex portion 69a and the convex portion 69b.

However, in such a case, before forming the glass ridge portion 66 and the resist layer 67, a metal layer of titanium, tantalum, or the like is formed on the surfaces thereof as a light blocking layer, which blocks an ultraviolet ray, with thickness equal to or larger than about 5 to 10 nm by a method such as sputtering. This makes it possible to reduce an influence of the irregular reflection of the ultraviolet ray.

In this glaze forming process (step 2 shown in (c) in FIG. 3 to step 6 shown in (c) in FIG. 4), first, the glass ridge portion 66 is formed (step 2) and, then, a part of the glass ridge portion 66 is removed by etching or the like (step 5) to pattern the glass ridge portion 66 and the glass flat portion 65 on which the convex portion 69a and the convex portion 69b are formed. However, a method of forming a glaze is not limited to such a formation process. Any other method may be used as long as equivalent convex portion 69a, convex portion 69b, and the like can be formed.

For example, it is also possible that, after forming the glass flat portion 65 and the glass ridge portion 66, a second glass layer is formed of second glass having a softening point lower than that of first glass forming the glass flat portion 65 and the glass ridge portion 66 and removed by etching or the like to pattern the convex portion 69a and the convex portion 69b. According to this method, it is possible to lower a heating temperature of the heat treatment process (step 7 shown in (d) in FIG. 4) performed to round the edges of the convex portion 69a and the convex portion 69b. Therefore, it is possible to prevent the glass flat portion 65 and the glass ridge portion 66, which are already formed in an optimum shape, from being changed by heat treatment.

In patterning the convex portion 69a and the convex portion 69b, in the above explanation, the second glass layer is formed over substantially the entire surface of the glass flat portion 65 and the glass ridge portion 66 and, then, the convex portion 69a and the convex portion 69b are formed by removing the second glass layer. However, instead of this method, it is also possible to use a lift-off method for forming, with a resist layer or the like, a reversal pattern of a positive/negative type on the convex portion 69a and the convex portion 69b as a masking pattern and, then, forming the convex portion 69a and the convex portion 69a according to a thin film formation method well known in the past such as sputtering or CVD (Chemical Vapor Deposition) and removing the masking pattern.

As described above, the glaze 21a (including the ridge portion 22a) having irregularities (at this stage, the convex portion 69a and the convex portion 69b) is formed in the glaze formation process shown in FIG. 3 and FIG. 4 (step 1 shown in (a) or (b) in FIG. 3 to step 6 shown in (c) in FIG. 4). The irregularities (the convex portion 69a and the convex portion 69b) are made gentle to form the convex portion 23a and the convex portion 23b in the heat treatment process (step 7 shown in (d) in FIG. 4). The heat element H1a, the heat element H1b, and the respective electrodes E are formed on the irregularities (the convex portion 23a and the convex portion 23b) of the ridge portion 22a of the glaze 21a in the following heat generating portion forming process (step 8 shown in (a) in FIG. 5 to step 10 shown in (c) in FIG. 5).

In step 8 (a part of the heat generating portion forming process) shown in (a) in FIG. 5, a thin film of the resistance material layer 24 to be formed as the heat element H1a and the heat element H1b (see FIG. 2) is formed on the surface of the glaze 21a including the ridge portion 22a on which the convex portion 23a and the convex portion 23b are formed. In forming the resistance material layer 24, it is possible to use sputtering or the like.

Thereafter, the aluminum layer 25 is formed on the resistance material layer 24. For the formation of the aluminum layer 25, as in the case of the resistance material layer 24, it is possible to use sputtering or the like. Further, a photo-resist for an etching resist is formed in a portion other than the heat element H1a and the heat element H1b (see FIG. 2) using an appropriate mask according to the photolithography method used in the field of semiconductor manufacturing. Instep 9 (apart of the heat generating portion forming process) shown in (b) in FIG. 5, after the aluminum layer 25 in an opening of the photo-resist is etched using appropriate etchant, the photo-resist is peeled off. Then, the aluminum layer 25 changes to the electrodes E and the heat element H1a and the heat element H1b are arrayed between the electrodes E.

Finally, in step 10 (the protective film forming process) shown in (c) in FIG. 5, to protect the heat element H1a, the heat element H1b, and the respective electrodes E, the protective film 26 of silicon dioxide is formed on the surfaces thereof by sputtering to coat the surfaces. Consequently, the thermal head 20-1 according to the first embodiment shown in FIG. 2 is manufactured.

### Second Embodiment

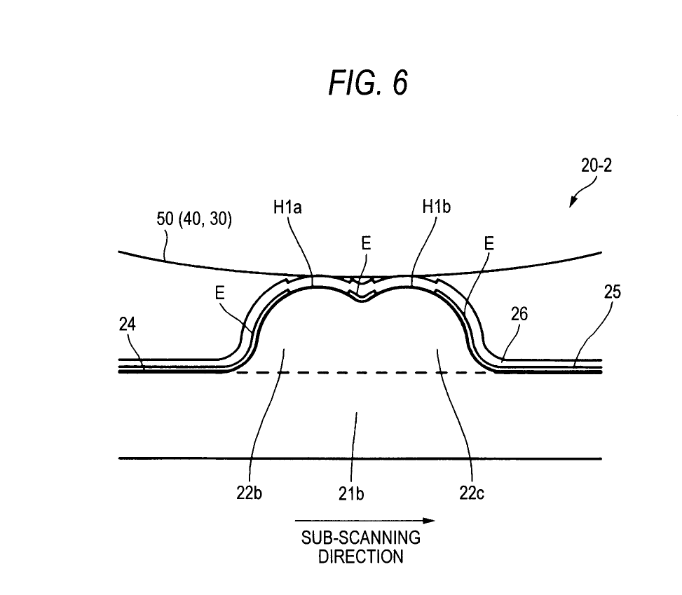

FIG. 6 is a sectional view in the sub-scanning direction showing a thermal head 20-2 according to a second embodiment of the present invention.

As shown in FIG. 6, a glaze 21b in the thermal head 20-2 according to the second embodiment is partially divided in the sub-scanning direction in association with the number of arrays (two rows) of the heat element row Ha and the heat element row Hb (see FIG. 1). The glaze 21b includes plural (two) partial ridge portions 22b and 22c of a ridge shape in sections thereof in the sub-scanning direction. The heat element H1a and the heat element H1b are arranged on upper sides of the partial ridge portion 22b and the partial ridge portion 22c.

As described above, in the thermal head 20-2 according to the second embodiment, the glaze 21b is partially divided into two near the top thereof. The partially divided portions are formed in a partial two-ridge shape in which sections of two ridges in the sub-scanning direction are semicircular, respectively. In this way, the partial ridge portion 22b and the partial ridge portion 22c are formed. The heat element H1a and the heat element H1b are arranged near the respective tops of the partial ridge portion 22b and the partial ridge portion 22c. The centers in the sub-scanning direction of the heat element H1a and the heat element H1b are located at the respective tops of the partial ridge portion 22b and the partial ridge portion 22c.

Therefore, in the thermal head 20-2 according to the second embodiment shown in FIG. 6, while a pressing force on the ink ribbon 50 (the recording sheet 40 and the platen roller 30) is maintained, both the heat element H1a and the heat element H1b have center positions in the sub-scanning direction near the respective tops of the partial ridge portion 22b and the partial ridge portion 22c. Therefore, “contact” of the partial ridge portion 22b and the partial ridge portion 22c is improved.

A method of manufacturing such a thermal head 20-2 (glaze 21b) according to the second embodiment is explained below.

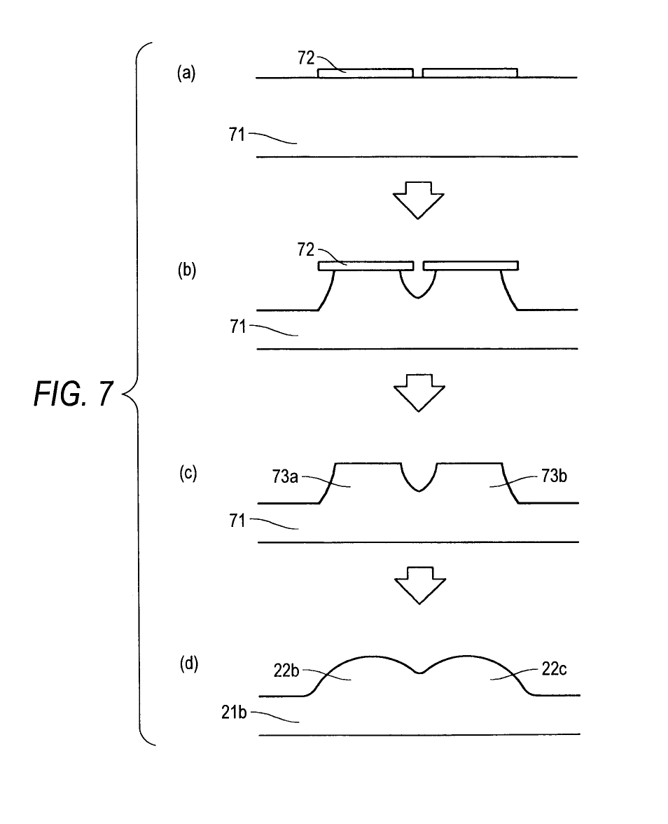

FIG. 7 shows sectional views in the sub-scanning direction showing an example of a glaze forming process (step 1 to step 4) in the method of manufacturing the thermal head 20-2 according to the second embodiment shown in FIG. 6.

First, in step 1 shown in (a) in FIG. 7, a glass flat portion 71 is formed with substantially uniform thickness over an entire surface of a substrate of alumina ceramics or the like (not shown) or at least an area of the substrate in which the glaze 21b is finally formed. A predetermined resist pattern 72 corresponding to the partial ridge portion 22b and the partial ridge portion 22c is formed on the glass flat portion 71.

Subsequently, in step 2 shown in (b) in FIG. 7, the glass flat portion 71 corresponding to an opening of the resist pattern 72 is etched to predetermined depth by, for example, wet etching using etchant containing hydro fluoric acid. Thereafter, in step 3 shown in (c) in FIG. 7, the resist pattern 72 is peeled off to obtain the glass flat portion 71 including a convex portion 73a and a convex portion 73b of predetermined height. In step 4 shown in (d) in FIG. 7, a rectangular pattern of the glass flat portion 71 is deformed into an R shape by performing intentional reflow or the like by heat treatment. The glaze 21b is manufactured with the convex portion 73a and the convex portion 73b formed as the partial ridge portion 22b and the partial ridge portion 22c.

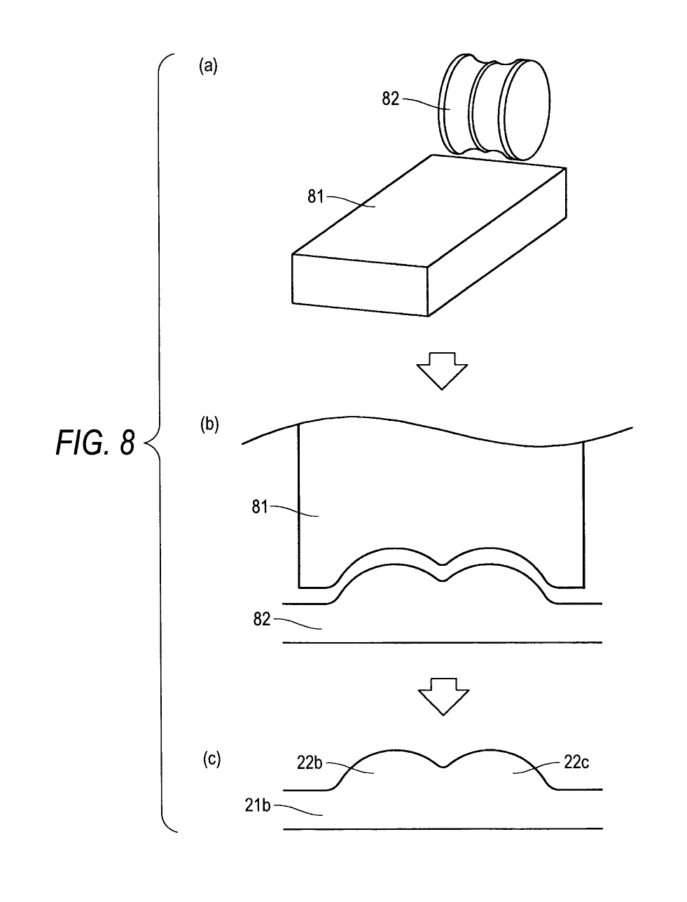

FIG. 8 shows sectional views in the sub-scanning direction showing another example of the glaze forming process (step 1 and step 2) in the method of manufacturing the thermal head 20-2 according to the second embodiment shown in FIG. 6.

In this example, in step 1 shown in (a) in FIG. 8, a glaze glass 81 is formed with substantially uniform thickness over an entire surface of a substrate of alumina ceramics or the like (not shown) or at least an area of the substrate in which the glaze 21b is finally formed.

Subsequently, in step 2 shown in (b) in FIG. 8, a rotating grindstone blade 82 for machining a partial two-ridge shape to be formed as the partial ridge portion 22b and the partial ridge portion 22c is rotated to cut the glaze glass 81 to form a desired partial two-ridge shape. In other words, a shape of the rotating grindstone blade 82 corresponds to the partial two-ridge shape desired to be formed. A rotating shaft (not shown) extending in parallel to the sub-scanning direction is provided in a rotation center of the rotating grindstone blade 82. The glaze glass 81 is kept parallel to the surface of the substrate (not shown). The glaze glass 81 is set at desired height and set in a jig (not shown) having a bank portion extending parallel to the main scanning direction. While the glaze glass 81 is kept in a state of contact with the bank portion, the rotating shaft of the rotating grindstone blade 82 advances in the main scanning direction. Therefore, when the rotating grindstone blade 82 is advanced in the main scanning direction while being rotated, as shown in (c) in FIG. 8, the partial ridge portion 22b and the partial ridge portion 22c can be formed with high accuracy.

According to the method in which the rotating grindstone blade 82 shown in FIG. 8 is used, the rectangular pattern is not deformed into the R shape by performing intentional reflow by heat treatment. Thus, there is no factor of fluctuation in a shape due to a change in heat treatment conditions, a temperature distribution of the entire substrate (not shown), and the like. The partial ridge portion 22b and the partial ridge portion 22c can be stably formed. In the method in which the rotating grindstone blade 82 is used, a predetermined sectional shape can be substantially fixed along a longitudinal direction in the main scanning direction and waviness and the like in that direction can be reduced. Therefore, it is possible to apply the method to any shape other than the partial two-ridge shape.

In the cutting by the rotating grindstone blade 82, for example, a grind with hyperfine diamond particles combined on the surface thereof is used and conditions such as rotation speed and feeding speed in the main scanning direction of the grindstone during machining are optimized to prevent chipping and the like from occurring on a machined surface as much as possible.

However, fine chipping may inevitably occur partially or fine irregularities may occur on the machined surface. As described above, thin films of the resistance material layer 24 (see FIG. 6) and the aluminum layer 25 (see FIG. 6) are formed on the surface after the machining by the method such as sputtering. Thus, if the chipping or the irregularities occur more than a certain degree, breaking of wire and the like are caused. Therefore, it is desirable to perform planarization treatment after the machining.

As the planarization treatment, for example, there is a method by buffing. In the buffing, a rotator, a surface of which is made of a member for buffing, is used in the same manner as a rotating grindstone and the rotator is fed in the main scanning direction while being brought into contact with a machined surface to polish the entire machined surface. Then, the fine irregularities, chipping, and the like caused by the cutting by the rotating grindstone blade 82 are eliminated and a smoother surface is obtained. As a result, in the thermal head 20-2 according to the second embodiment shown in FIG. 6, reliability of the heat element H1a, the heat element H1b, and the respective electrodes E formed by the resistance material layer 24 and the aluminum layer 25 on the smooth surface is improved.

As another method of the planarization treatment, there is light etching (soft etching). This is a method of performing light etching using etchant that is capable of etching the glaze glass 81. As the etchant, for example, it is possible to use hydro fluoric acid water solution and the like. In the case of the planarization treatment, the density of hydro fluoric acid is set thinner than that in usual etching and etching is performed in a short time to preferentially etch fine convex portions.

Moreover, a method by heating treatment is also possible as another method of the planarization treatment. This is a method of performing heat treatment in a short time at temperature higher than a softening point of glass of the glaze glass 81. According to such heating treatment, it is possible to smooth a machined surface in the cutting by the rotating grindstone blade 82.

### Third Embodiment

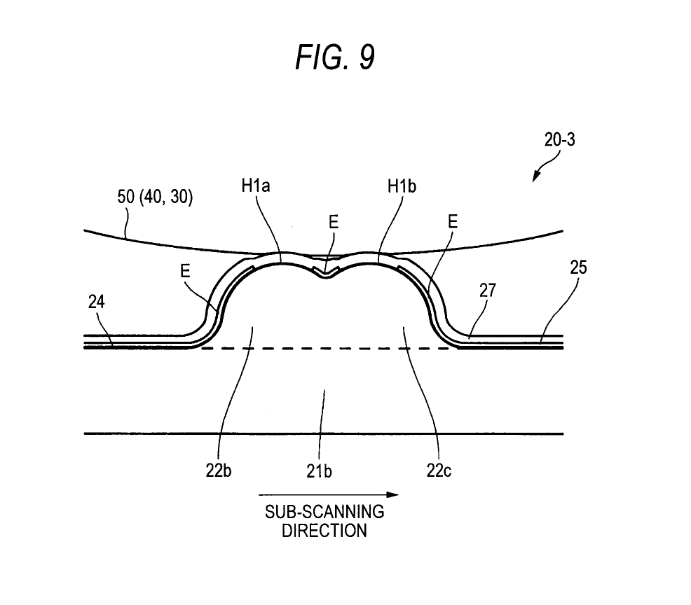

FIG. 9 is a sectional view in the sub-scanning direction showing a thermal head 20-3 according to a third embodiment of the present invention.

As in the thermal head 20-2 according to the second embodiment shown in FIG. 6, in the thermal head 20-3 according to the third embodiment shown in FIG. 9, the heat element H1a and the heat element H1b are arranged on the upper sides of the partial ridge portion 22b and the partial ridge portion 22c, respectively. However, a step of a protective film 27 is set small.

The step of the protective film 27 is set small to eliminate a problem of “sticking” and the like. In the thermal head 20-2 according to the second embodiment shown in FIG. 6, a step due to the thickness of the aluminum layer 25 occurs on the surface of the protective film 26 (see FIG. 6). When this step is large, the ink ribbon 50 and the recording sheet 40 heated by the heat element H1a and the heat element H1b are caught on the step and conveyed while being caught. This is the problem of “sticking”. In particular, when the heat element H1a and the heat element H1b are formed with high density corresponding to the resolution of 600 DPI, in addition to “contact” of the heat element H1a and the heat element H1b, the problem of “sticking” and the like due to the step of the protective film 26 more easily occurs. This problem should not be overlooked. Thus, in the thermal head 20-3 according to the third embodiment, the step of the protective film 27 is set smaller than 0.01 μm.

The step of the protective film 26 (see FIG. 6) can be made gentle by, for example, a polishing process after the protective film forming process (step 10 shown in (c) in FIG. 5). After the protective film 26 is formed, a portion having the step is removed by polishing. The polishing of the step does not always have to be performed after the protective film 26 is completely formed.

In the polishing process, after a first protective film is intentionally formed with low density by sputtering, only portions of the first protective film near the heat element H1a and the heat element H1b are selectively polished by properly using abrasives having different grain sizes to reduce the step to be smaller than 0.01 μm. When the step of the first protective film is reduced to be smaller than 0.01 μm in this way, finally, a second protective film of silicon dioxide or the like is formed on the first protective film with high density by sputtering. As a result, the thermal head 20-3 according to the third embodiment in which the protective film 27 (the first protective film+the second protective film) having the step smaller than 0.01 μm is formed is obtained. Thus, “contact” of the thermal head 20-3 in which the heat element H1a and the heat element H1b are arrayed with high density of 600 DPI is improved. It is possible to prevent the problem of “sticking” and the like.

### Fourth Embodiment

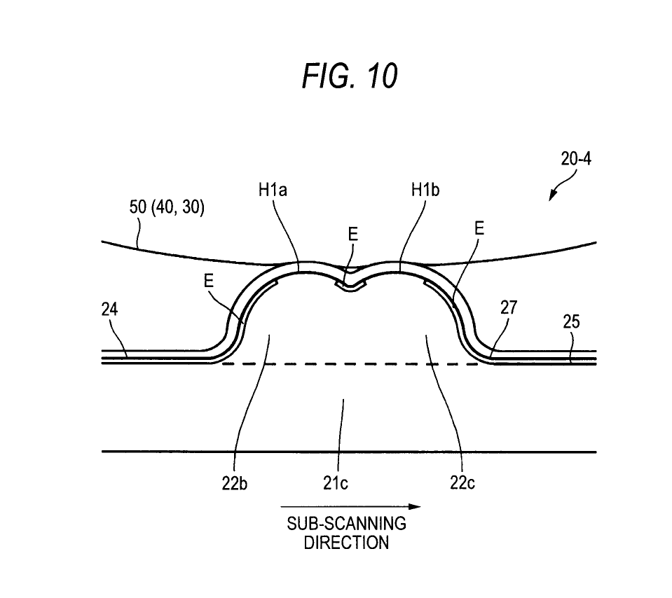

FIG. 10 is a sectional view in the sub-scanning direction showing a thermal head 20-4 according to a fourth embodiment of the present invention.

As in the thermal head 20-3 according to the third embodiment shown in FIG. 9, in the thermal head 20-4 according to the fourth embodiment shown in FIG. 10, the protective film 27 with a step reduced is formed. However, a step hardly occurs because of a change in the structure of the resistance material layer 24 and the aluminum layer 25.

In the thermal head 20-4 according to the fourth embodiment, a glaze 21c obtained by forming the partial ridge portion 22b and the partial ridge portion 22c according to the method shown in (a) to (d) in FIG. 7 or (a) to (c) in FIG. 8 and, then, removing a part of the surfaces thereof corresponding to a wiring pattern according to the thickness of the aluminum layer 25 is used. The aluminum layer 25 is embedded in a concave portion formed by the removal and the resistance material layer 24 is formed on the aluminum layer 25. Then, compared with the thermal head 20-3 according to the third embodiment shown in FIG. 9, vertical positions of the resistance material layer 24 and the aluminum layer 25 are interchanged. An upper surface of the aluminum layer 25 embedded in the concave portion is set to be at the same level as the surfaces of the partial ridge portion 22b and the partial ridge portion 22c.

By embedding the aluminum layer 25 in the partial ridge portion 22b and the partial ridge portion 22c in this way, the projection of the aluminum layer 25, which is a main cause of occurrence of the step of the protective film 27, is eliminated. In this case, a step due to the thickness of the resistance material layer 24 formed on the aluminum layer 25 occurs. However, since the thickness of the resistance material layer 24 is usually about 0.1 μm, a step that occurs in the protective layer 27 is the same size. This is extremely small compared with a step due to the aluminum layer 25 having the thickness of about 1 μm. Therefore, an influence of the step is negligible or, even if there is an influence of the step, the influence is extremely small.

An area in which the glaze 21c is embedded only has to be at least a connecting portion (a portion where a step occurs) of the respective electrodes E formed by the aluminum layer 25. The elimination of the step of the protective film 27 is explained above citing the thermal head 20-3 according to the third embodiment (see FIG. 9) and the thermal head 20-4 according to the fourth embodiment (see FIG. 10) including the partial ridge portion 22b and the partial ridge portion 22c as examples. However, the method and the structure for eliminating a step can also be applied to the thermal head 20-1 according to the first embodiment including the ridge portion 22a shown in FIG. 2.

In the case of the thermal head 20-1 according to the first embodiment shown in FIG. 2, the electrode connecting portions C opposed to each other in the sub-scanning direction are located in the positions lower than the highest portions of the heat element H1a and the heat element H1b. Therefore, the edge portion (the step) of the protective film 26 (see FIG. 2) between the heat element H1a and the heat element H1b does not come into contact with the ink ribbon 50 (the recording sheet 40 and the platen roller 30). It is considered to be unnecessary to remove the step of the protective film 26.

However, the step of the protective film 26 may inevitably occur in an upper part or an inclined portion of the convex portion 23a or the convex portion 23b shown in FIG. 2 when the space between the heat element H1a and the heat element H1b is reduced or because of, for example, design of the length in the sub-scanning direction of the heat element H1a or the heat element H1b. Therefore, in such a case, since it is necessary to eliminate the step, it is also effective in the thermal head 20-1 according to the first embodiment (see FIG. 2) to adopt the method and the structure explained concerning the thermal head 20-3 according to the third embodiment (see FIG. 9) or the thermal head 20-4 according to the fourth embodiment (see FIG. 10).

### Fifth Embodiment

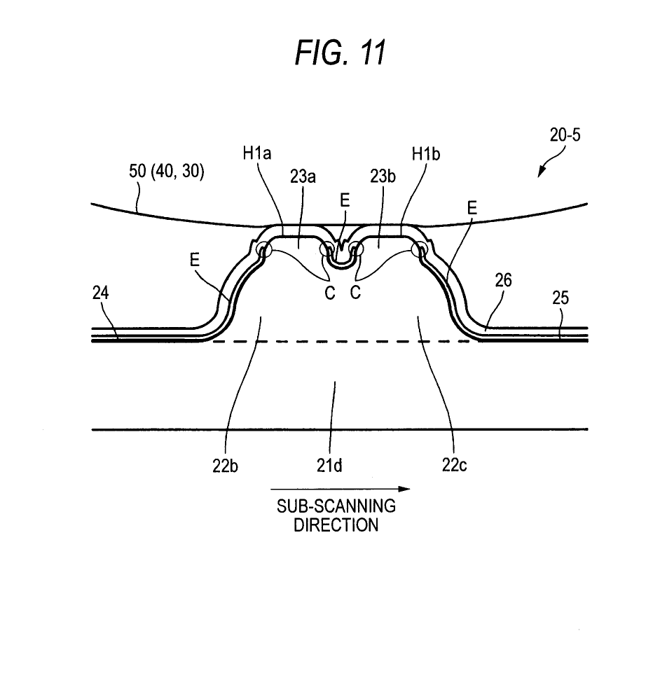

FIG. 11 is a sectional view in the sub-scanning direction showing a thermal head 20-5 according to a fifth embodiment of the present invention.

Like the thermal head 20-2 according to the second embodiment shown in FIG. 6, the thermal head 20-5 according to the fifth embodiment shown in FIG. 11 includes the partial ridge portion 22b and the partial ridge portion 22c. However, the convex portion 23a and the convex portion 23b same as those in the thermal head 20-1 according to the first embodiment shown in FIG. 2 are further formed on the upper sides of the partial ridge portion 22b and the partial ridge portion 22c.

As in the thermal head 20-1 according to the first embodiment (see FIG. 2), the heat element H1a and the heat element H1b are arranged near the tops of the convex portion 23a and the convex portion 23b, respectively. Therefore, positions of the electrode connecting portions C opposed to each other in the sub-scanning direction of the heat element H1a and the heat element H1b are lower than the highest portions of the heat element H1a and the heat element H1b. Thus, the edge portion of the protective film 26 between the heat element H1a and the heat element H1b does not come into contact with the ink ribbon 50 (the recording sheet 40 and the platen roller 30).

In the thermal head 20-5 according to the fifth embodiment, bases of the convex portion 23a and the convex portion 23b are the partial ridge portion 22b and the partial ridge portion 22c. Thus, the respective tops of the convex portion 23a and the convex portion 23b formed at the tops of the partial ridge portion 22b and the partial ridge portion 22c are in highest positions in the entire thermal head 20-5 and have a substantially horizontal shape over the length in the sub-scanning direction or a gentle curved surface shape symmetrical with respect to the tops. Therefore, “contact” of the heat element H1a and the heat element H1b is further improved. A glaze 21d including the partial ridge portion 22b and the partial ridge portion 22c on which the convex portion 23a and the convex portion 23b are formed can be manufactured by, for example, matching a shape of the rotating grindstone blade 82 shown in FIG. 8 to the glaze 21d.

### Sixth Embodiment

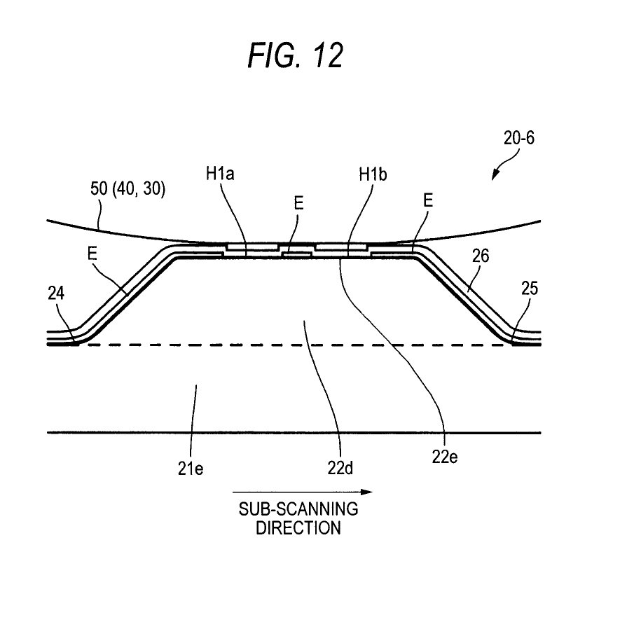

FIG. 12 is a sectional view in the sub-scanning direction showing a thermal head 20-6 according to a sixth embodiment of the present invention.

As shown in FIG. 12, a glaze 21e in the thermal head 20-6 according to the sixth embodiment includes a ridge portion 22d of a ridge shape in a section thereof in the sub-scanning direction and a flat portion 22e formed at the top of the ridge portion 22d. The heat element H1a and the heat element H1b are arranged on an upper side of the flat section 22e. In the thermal head 20-6 according to the sixth embodiment, each of the heat element row Ha and the heat element row Hb (see FIG. 1) arrayed in plural rows (two rows) in the sub-scanning direction is arranged on the upper side of the flat portion 22e.

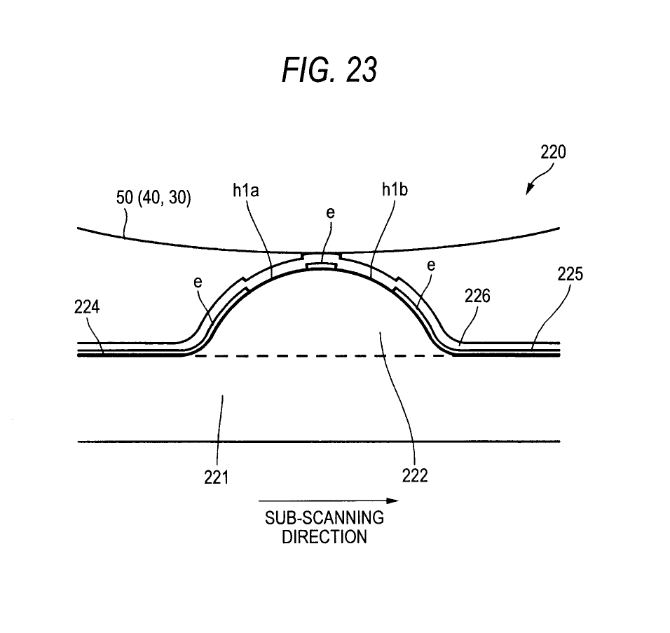

As described above, the glaze 21e in the thermal head 20-6 according to the sixth embodiment has a trapezoidal shape in the section in the sub-scanning direction. The heat element H1a and the heat element H1b are arranged on the upper side of the flat portion 22e. Therefore, compared with the glaze 22l in the thermal head 220 in the past shown in FIG. 23, “contact” of the heat element H1a and the heat element H1b is improved.

The width of the glaze 21e is larger than that of the glaze 22l. The section of the glaze 21e is not limited to the trapezoidal shape and only has to be formed by the ridge portion 22d of a semicircular shape or a gentle ridge shape similar to the semicircular shape and the flat portion 22e (a highest portion in the glaze 21e) formed by at least partially removing the tops where the heat element H1a and the heat element H1b are arranged. It is desirable to form a boundary portion of the ridge portion 22d and the flat portion 22e in an R shape shown in FIG. 12 not to be square.

A method of manufacturing the thermal head 20-6 (the glaze 21e) according to the sixth embodiment is explained.

To manufacture the glaze 21e of the thermal head 20-6 according to the sixth embodiment, glaze glass formed flat on a substrate of alumina ceramics or the like is etched or otherwise machined to be formed as the ridge portion 22d of the ridge shape (the trapezoidal shape) in which the flat portion 22e is formed. The glaze glass is subjected to heat treatment at temperature higher than a softening point of glass of the glaze glass. In performing the heat treatment, a heat treatment time is set shorter than that in forming the glass ridge portion 66 of the semicircular shape shown in (c) in FIG. 3 and deformation into an R shape due to reflow is reduced to make corners in an upper part and a lower part of the ridge portion 22d smooth while maintaining the flat portion 22e. In this way, in manufacturing the glaze 21e, it is possible to directly use an apparatus generally used in the past and addition or the like of a special manufacturing apparatus is unnecessary.

Such a glaze 21e can also be manufactured by matching a shape of the rotating grindstone blade 82 shown in FIG. 8 to the glaze 21e. According to this manufacturing method, the process of deformation into an R shape by heating and reflow is unnecessary. Therefore, there is no factor of fluctuation in a shape due to a change in heat treatment conditions, a temperature distribution of the entire substrate, and the like. It is possible to stably form a shape including the flat portion 22e.

Moreover, the step of the protective film 26 is eliminated by polishing as in the thermal head 20-3 according to the third embodiment (see FIG. 9) or eliminated by embedding the aluminum layer 25 in the glaze 21e as in the thermal head 20-4 according to the fourth embodiment (see FIG. 10). In this way, it is also possible to further improve “contact” of the heat element H1a and the heat element H1b.

### Seventh Embodiment

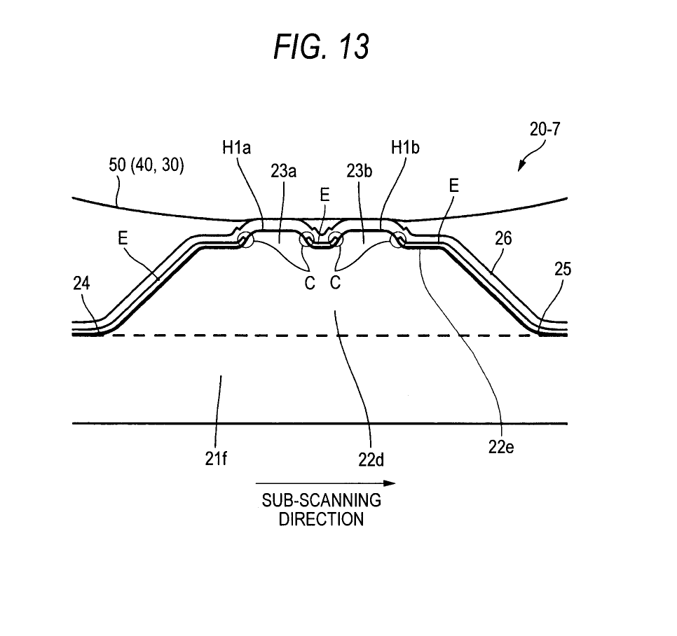

FIG. 13 is a sectional view in the sub-scanning direction showing a thermal head 20-7 according to a seventh embodiment of the present invention.

Like the thermal head 20-6 according to the sixth embodiment shown in FIG. 12, the thermal head 20-7 according to the seventh embodiment shown in FIG. 13 includes the ridge portion 22d and the flat portion 22e. However, the convex portion 23a and the convex portion 23b same as those in the thermal head 20-1 according to the first embodiment shown in FIG. 2 are further formed on the upper side of the flat portion 22e.

As in the thermal head 20-1 (see FIG. 2) according to the first embodiment, the heat element H1a and the heat element H1b are arranged near the tops of the convex portion 23a and the convex portion 23b, respectively. Therefore, positions of the electrode connecting portions C opposed to each other in the sub-scanning direction of the heat element H1a and the heat element H1b are lower than the highest portions of the heat element H1a and the heat element H1b. Thus, the edge portion of the protective film 26 between the heat element H1a and the heat element H1b does not come into contact with the ink ribbon 50 (the recording sheet 40 and the platen roller 30).

The respective tops of the convex portion 23a and the convex portion 23b formed on the upper side of the flat portion 22e are in highest positions in the entire thermal head 20-7 and have a substantially horizontal shape over the length in the sub-scanning direction or a gentle curved surface shape symmetrical with respect to the tops. Therefore, “contact” of the heat element H1a and the heat element H1b is further improved. The “contact” of the heat element H1a and the heat element H1b is improved because the convex portion 23a and the convex portion 23b are formed on the upper side of the flat portion 22e. In other words, the height of the ridge portion 22d hardly affects a quality of “contact”. Therefore, it is also possible to set the height of the ride portion 22d to “0” (remove the ridge portion 22d and directly form the convex portion 23a and the convex portion 23b on a flat surface).

In the thermal head 20-7 according to the seventh embodiment, the electrode connecting portions C opposed to each other in the sub-scanning direction are in positions lower than the highest portions of the heat element H1a and the heat element H1b. Therefore, the edge portion (the step) of the protective film 26 between the heat element H1a and the heat element H1b does not come into contact with the ink ribbon 50 (the recording sheet 40 and the platen roller 30). It is considered unnecessary to remove the step of the protective film 26.

However, the step of the protective film 26 may inevitably occur in an upper part or an inclined portion of the convex portion 23a or the convex portion 23b when the space between the heat element H1a and the heat element H1b is reduced or because of, for example, design of the length in the sub-scanning direction of the heat element H1a or the heat element H1b. Therefore, in such a case, since it is necessary to eliminate the step, it is also possible to eliminate the step of the protective film 26 and improve “contact” of the heat element H1a and the heat element H1b by adopting the method and the structure explained concerning the thermal head 20-3 according to the third embodiment (see FIG. 9) or the thermal head 20-4 according to the fourth embodiment (see FIG. 10).

A method of manufacturing the thermal head 20-7 (a glaze 21f) according to the seventh embodiment is explained.

To manufacture the glaze 21f of the thermal head 20-7 according to the seventh embodiment, glaze glass formed flat on a substrate of alumina ceramics or the like is etched or otherwise machined to form the ridge portion 22d of the ridge shape (the trapezoidal shape), the flat portion 22e at the top of the ridge portion 22d, and rectangular portions corresponding to the convex portion 23a and the convex portion 23b on the flat portion 22e. Thereafter, corners of the respective portions are smoothed by heat treatment to obtain the glaze 21f.

The glaze 21f can also be manufactured by matching a shape of the rotating grindstone blade 82 shown in FIG. 8 to the glaze 21f. According to this manufacturing method, it is possible to collectively form a complicated shape including the convex portion 23a and the convex portion 23b on the flat portion 22e of the ridge portion 22d. Thus, it is possible to further simplify the process while maintaining shape accuracy.

Moreover, it is also possible to form the ridge portion 22d, the flat portion 22e, the convex portion 23a, and the convex portion 23b by first forming a shape obtained by removing a part of a reference shape of a semicircular shape and a gentle ridge shape similar to the semicircular shape in a section thereof along the sub-scanning direction such that at least a portion corresponding to an area in which the heat element H1a and the heat element H1b are arranged is formed as a flat surface and, then, performing etching and heat treatment. According to this method, even when the convex portion 23a and the convex portion 23b are fine, it is difficult to match a shape of the rotating grindstone blade 82 to the convex portion 23a and the convex portion 23b, and it is difficult to collectively machine the portions, it is possible to form the convex portion 23a and the convex portion 23b by etching and heat treatment (deformation into an R shape) in a short time after the etching. Since the heat treatment is performed in a short time, flatness of the flat portion 22e is maintained.

### Eighth Embodiment

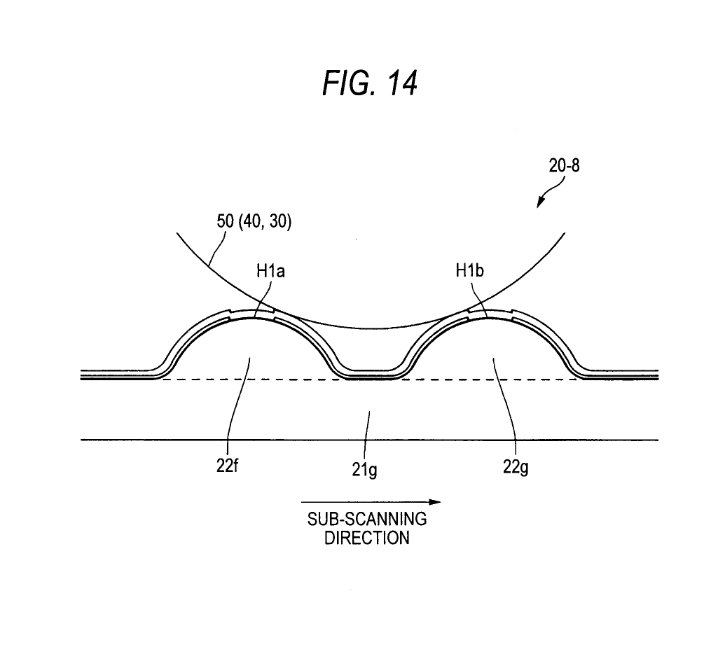

FIG. 14 is a sectional view in the sub-scanning direction showing a thermal head 20-8 according to an eighth embodiment of the present invention.

As shown in FIG. 14, a glaze 21g in the thermal head 20-8 according to the eighth embodiment includes plural (two) ridge portions 22f and 22g that are arranged in the sub-scanning direction in association with the number of arrays (two rows) of the heat element row Ha and the heat element row Hb (see FIG. 1) and are a ridge shape in sections thereof in the sub-scanning direction. The heat element H1a and the heat element H1b are arranged on upper sides of the ridge portion 22f and the ridge portion 22g.

As described above, in the thermal head 20-8 according to the eighth embodiment, the glaze 21g includes the separate ridge portions 22f and 22g. The sections in the sub-scanning direction of the ridge portion 22f and the ridge portion 22g are formed in a two-ridge shape of a semicircular shape. The heat element H1a and the heat element H1b are arranged near the tops of the ridge portion 22f and the ridge portion 22g. The centers in the sub-scanning direction of the heat element H1a and the heat element H1b are located at the tops of the ridge portion 22f and the ridge portion 22g.

Therefore, in the thermal head 20-8 according to the eighth embodiment shown in FIG. 14, while a pressing force on the ink ribbon 50 (the recording sheet 40 and the platen roller 30) is maintained, both the heat element H1a and the heat element H1b have center positions in the sub-scanning direction near the respective tops of the ridge portion 22f and the ridge portion 22g. Therefore, “contact” of the ridge portion 22f and the ridge portion 22g is improved. The ridge portion 22f and the ridge portion 22g can be formed by etching, cutting or the like by the rotating grind blade 82 (see FIG. 8), and the like.

### Ninth Embodiment

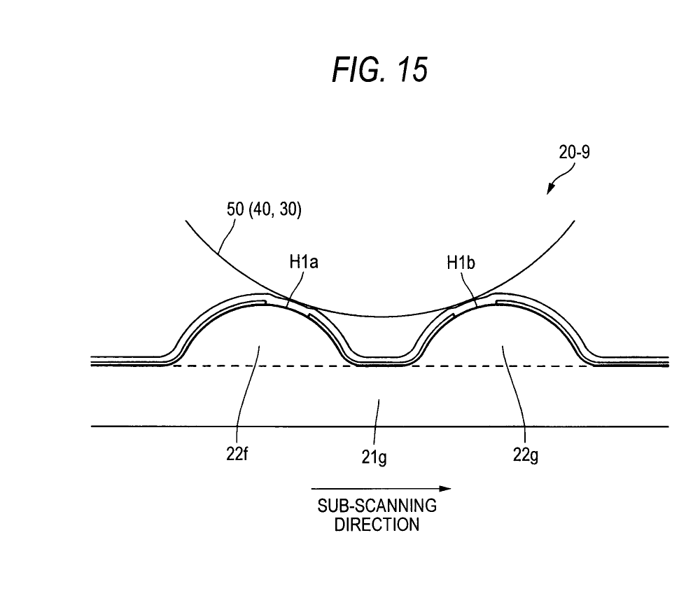

FIG. 15 is a sectional view in the sub-scanning direction showing the thermal head 20-9 according to a ninth embodiment of the present invention.

Like the thermal head 20-8 according to the eighth embodiment shown in FIG. 14, the thermal head 20-9 according to the ninth embodiment shown in FIG. 15 includes the ridge portion 22f and the ridge portion 22g. However, the arrangement of the heat element H1a and the heat element 11b is shifted closer to the center between the heat elements in the sub-scanning direction than the tops of the ridge portion 22f and the ridge portion 22g.

The heat element H1a and the heat element H1b are arranged to be shifted closer to the center between the heat elements to further improve “contact”. In other words, when a space between the ridge portion 22f and the ridge portion 22g increases, contact positions of the ridge portion 22f and the ridge portion 22 with an outer circumference of the platen roller 30 shift closer to the center between the ridge portions. Therefore, the heat element H1a and the heat element H1b are arranged on slop portions slightly down closer to the center between the ridge portion 22f and the ridge portion 22g from the respective tops of the ridge portions to match the contact positions and “contact” is improved.

### Tenth Embodiment

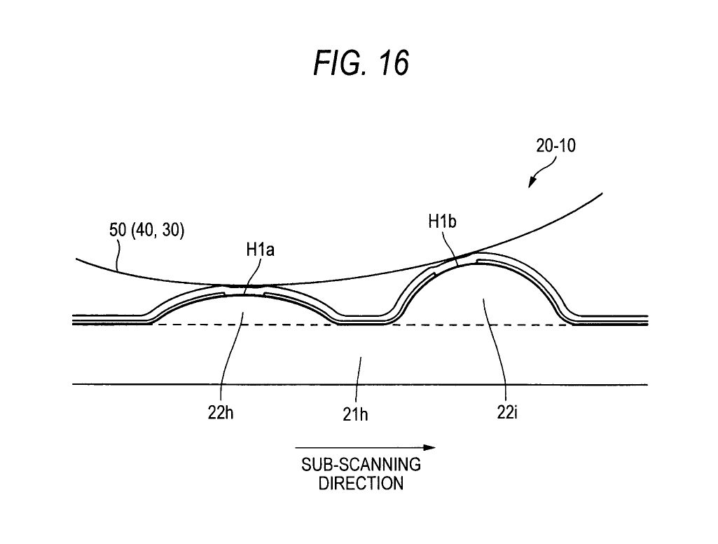

FIG. 16 is a sectional view in the sub-scanning direction showing a thermal head 20-10 according to a tenth embodiment of the present invention.

Like the thermal head 20-8 according to the eighth embodiment shown in FIG. 14, the thermal head 20-10 according to the tenth embodiment shown in FIG. 16 has a two-ridge shape. However, a glaze 21h includes a low ridge portion 22h and a high ridge portion 22i having different heights according to an outer diameter of the platen roller 30 opposed to the glaze 21h.

The glaze 21h has the low ridge portion 22h and the high ridge portion 22i in this way to improve “contact”. In other words, although the low ridge portion 22h is formed relatively lower than the high ridge portion 22i, the heat element H1a is arranged at the top of the low ridge portion 22h. On the other hand, the high ridge portion 22i is formed relatively higher than the low ridge portion 22h. The heat element H1b is arranged on a slope portion slightly down closer to the center between the ridge portions from the top. Therefore, since the heat element H1a and the heat element H1b are arranged in contact positions of the platen roller 30 along the outer circumference of the platen roller 30, “contact” is improved.

### Eleventh Embodiment

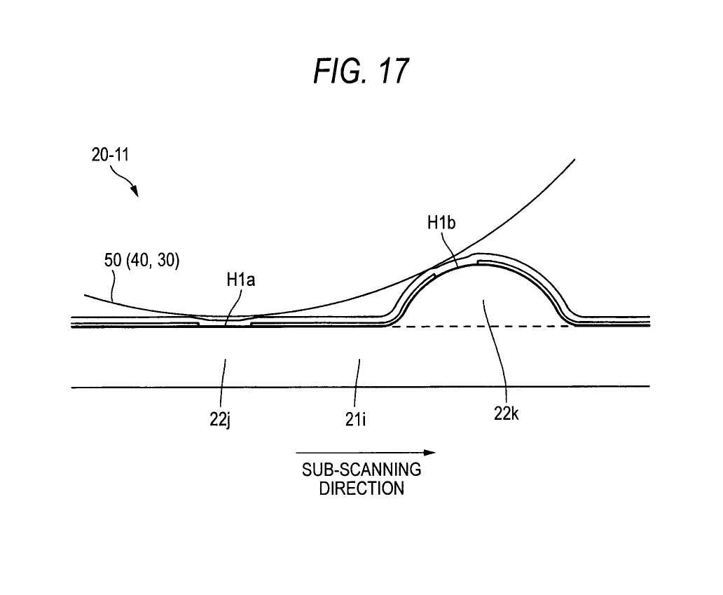

FIG. 17 is a sectional view in the sub-scanning direction showing a thermal head 20-11 according to an eleventh embodiment of the present invention.

In the thermal head 20-11 according to the eleventh embodiment shown in FIG. 17, the height of the low ridge portion 22h in the thermal head 20-10 according to the tenth embodiment shown in FIG. 16 is set to “0”. In other word, the low ridge portion 22h (see FIG. 16) is removed and a glaze 21i including a flat base portion 22j and a ridge portion 22k is used.

The glaze 21i includes the flat base portion 22j and the ridge portion 22k to improve “contact”. In other words, the heat element H1a is arranged on an upper side of the base section 22j and the heat element H1b is arranged on an upper side of the ridge portion 22k but on a slope portion slightly down closer to the center between the flat base portion 22j and the ridge portion 22k from the top of the ridge portion 22k.

Therefore, since the heat element H1a and the heat element H1b are arranged in contact positions of the platen roller 30 along the outer circumference of the platen roller 30, “contact” is improved.

In such a glaze 21i, although a pressing force of the platen roller 30 in the base section 22j is rather low, only one ridge portion 22k is provided. Therefore, the glaze 21i is effective for improvement of “contact”, in particular, when it is difficult to form the two ridge portions 22f and 22g (FIG. 14) or when it is possible to form the two ridge portions 22f and 22g but there is a problem of cost because of a glaze forming process, a manufacturing apparatus, or the like. It is also possible to set a pressing force of the thermal head 20-11 slightly large and increase the sinking of the platen roller 30 to improve “contact”.

### Twelfth Embodiment

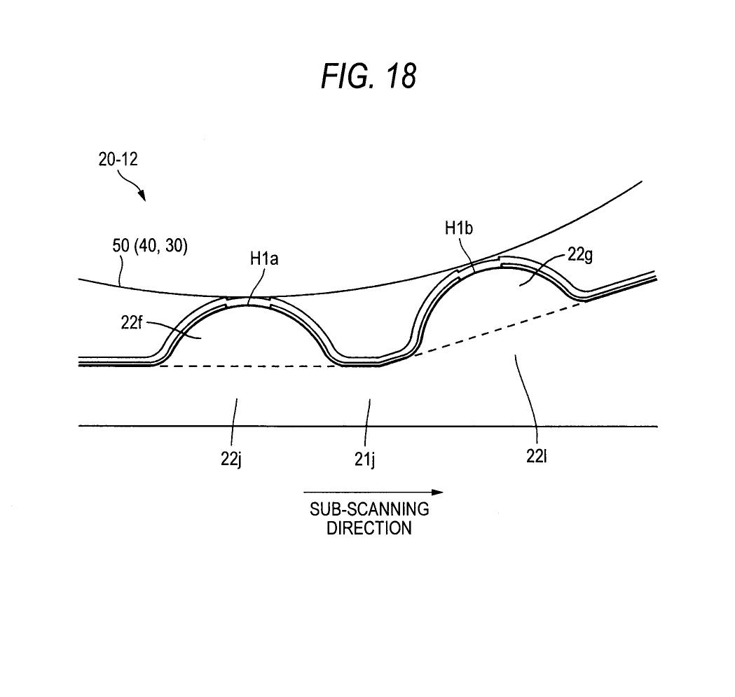

FIG. 18 is a sectional view in the sub-scanning direction showing a thermal head 20-12 according to a twelfth embodiment of the present invention.

The thermal head 20-12 according to the twelfth embodiment shown in FIG. 18 uses a glaze 21j including a flat base portion 22j and an inclined portion 22l inclined according to the outer diameter of the platen roller 30 opposed thereto unlike the glaze 21g in the thermal head 20-8 according to the eighth embodiment shown in FIG. 14. The ridge portion 22f and the ridge portion 22g are separately located on the upper sides of the base portion 22j and the inclined portion 22l.

The heat element H1a and the heat element H1b are arranged near the respective tops of the ridge portion 22f and the ridge portion 22g. The centers in the sub-scanning direction of the heat element H1a and the heat element H1b are located at the respective tops of the ridge portion 22f and the ridge portion 22g. However, the ridge portion 22g is located on the inclined portion 22l inclined according to the outer diameter of the platen roller 30. Therefore, the ridge portion 22f and the ridge portion 22g are inclined relatively to each other. The heat element H1a and the heat element H1b are arranged in contact positions of the platen roller 30 along the outer circumference of the platen roller 30. Therefore, “contact” is improved.

The heat element H1a and the heat element H1b may be arranged on slope portions slightly down closer to the center between the ridge portion 22f and the ridge portion 22g from the tops of the ridge portions rather than being arranged near the respective tops of the ridge portions. In other words, the centers in the sub-scanning directions of the heat element H1a and the heat element H1b only have to be located in optimum positions depending on a dimension relation among curvature radiuses and heights of the ridge portion 22f and the ridge portion 22g of a semicircular shape, a space between the ridge portions, the outer diameter of the platen roller 30, and the like. It is also possible to provide plural inclined portions 22l or remove the base portion 22j and provide only the plural inclined portions 22l.

### Thirteenth Embodiment

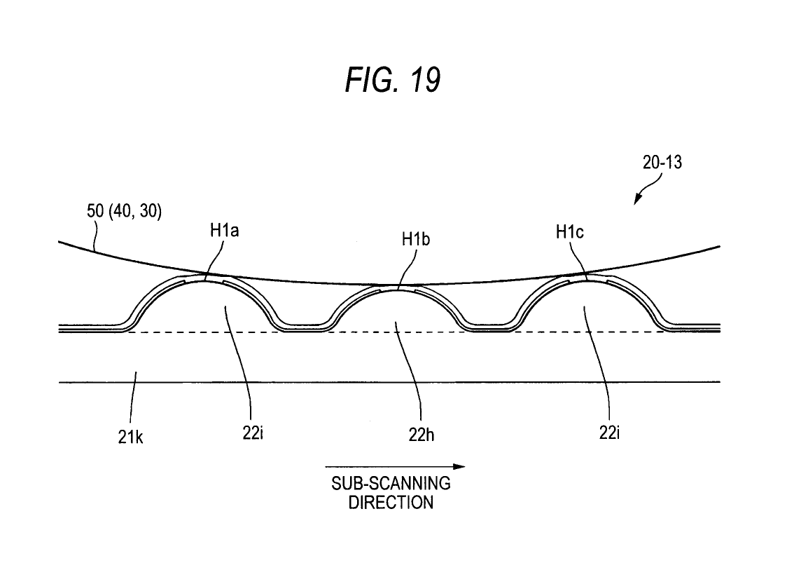

FIG. 19 is a sectional view in the sub-scanning direction showing a thermal head 20-13 according to a thirteenth embodiment of the present invention.

In the thermal head 20-13 according to the thirteenth embodiment shown in FIG. 19, the number of high ridge portions 22i in the thermal head 20-10 according to the tenth embodiment shown in FIG. 16 is increased to two. The high ridge portions 22i are combined with the low ridge portion 22h to form a three-ridge shape. In other words, when a heat element row Hc is added to the heat element row Ha and the heat element row Hb shown in FIG. 1, since the number of arrays is three, the three ridge portions (the one low ridge portion 22h and the two high ridge portions 22i) are provided in association with the number of arrays. The heat element H1a, the heat element H1b, and a heat element H1c are arranged in the ridge portions, respectively. In the heat element row Hc, a plurality of the heat elements H1c are arrayed in the main scanning direction.

When there are three low ridge portions 22h, when there are three high ridge portions 22i, or when the heights of all the ridge portions are identical, relatively satisfactory “contact” is obtained in the centers of the ridge portions. However, since the platen roller 30 has a cylindrical shape long in the main scanning direction, “contact” at both ends of the ridge portions is extremely poor. Therefore, in the thermal head 20-13 according to the thirteenth embodiment, the low ridge portion 22h is arranged in the center and the high ridge portions 22i are arranged on both sides of the low ridge portion 22h, respectively, along the outer circumference of the platen roller 30 to improve the “contact”. Even when the number of arrays of the heat element rows is increased to be equal to or more than three, ridge portions can be arranged in the same manner.

### Fourteenth Embodiment

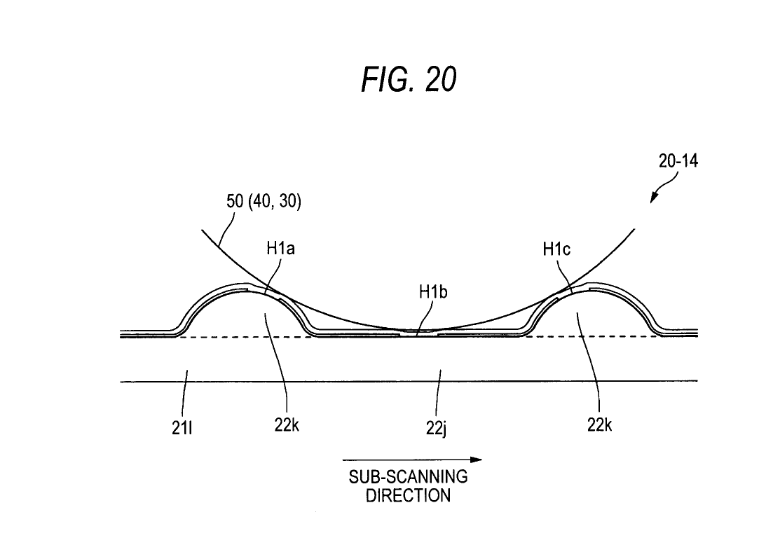

FIG. 20 is a sectional view in the sub-scanning direction showing a thermal head 20-14 according to a fourteenth embodiment of the present invention.

In the thermal head 20-14 according to the fourteenth embodiment shown in FIG. 20, the height of the low ridge portion 22h in the thermal head 20-13 according to the thirteenth embodiment shown in FIG. 19 is set to “0”. Alternatively, the number of ridge portions 22k in the thermal head 20-11 according to the eleventh embodiment shown in FIG. 17 is increased to two. In other words, in the thermal head 20-14 according to the fourteenth embodiment, the glaze 21l including the flat base portion 22j and the two ridge portions 22k is used.

The glaze 21l includes the flat base portion 22j and the two ridge portions 22k in this way to further improve “contact”. The heat element H1a and the heat element H1c are arranged on the upper sides of the ridge portions 22k but on slope portions slightly down closer to the center between the ridge portions from the tops, respectively. The heat element H1b is arranged on the upper side of the base portion 22j. Therefore, since the heat element H1a, the heat element H1b, and the heat element H1c are arranged in contact positions of the platen roller 30 along the outer circumference of the platen roller 30, “contact” is improved.

In such a glaze 21l, the flat base portion 22j and the two ridge portions 22k are provided along the outer circumference of the platen roller 30 and “contact” is improved in all the heat element H1a, the heat element H1b, and the heat element H1c. Although a pressing force of the paten roller 30 is rather low in the base portion 22j, compared with the thermal head 20-13 according to the thirteenth embodiment (see FIG. 19), only the two ridge portions 22k having the same height only have to be formed. Therefore, for example, even when it is difficult to form the three ridge portions (the one low ridge portion 22h and the two ridge portions 22i) shown in FIG. 19 or when it is difficult to form the ridge portions having the different heights (the low ridge portion 22h and the high ridge portion 22i) because of a glaze forming process, a manufacturing apparatus, or the like, the glaze 21l is effective for improvement of “contact” and in terms of cost. It is also possible to set a pressing force of the thermal head 20-14 slightly large and increase the sinking of the platen roller 30 to improve “contact”.

Therefore, according to the present invention, the thermal head 20 that has improved “contact” of the respective heat elements H, can perform high-speed recording, and is excellent in a recording quality can be realized. During ultrahigh-speed recording, excessive temperature rise of the thermal head 20 is prevented and further deterioration in the thermal head 20 is suppressed. As a result, it is possible to extend the durable life of the thermal head 20. Since excessive temperature rise of the thermal head 20 during ultrahigh-speed recording is prevented, it is possible to prevent the fall in a recording quality due to occurrence of “tailing” or the like. Moreover, it is possible to realize high definition of a formed image while realizing high-speed recording using the thermal head 20 in which the respective heat elements H are arranged with high density (e.g., 600 DPI). Furthermore, by setting the step of the protective film 26 to be smaller than 0.01 μm, it is possible to prevent the problem of “sticking” and the like while arranging the respective heat elements H with high density (e.g., 600 DPI).

The embodiments of the present invention have been explained. However, the present invention is not limited to the embodiments described above. For example, various modifications described below are possible.

(1) The thermal head 20 can be applied not only to the sublimation transfer system for transferring dye held on the ink ribbon 50 onto the recording sheet 40 to record an image and the like but also to, for example, a heat sensitive type system for recording an image and the like on the recording sheet 40 of a heat sensitive type without using the ink ribbon 50.

(2) The number of arrays of heat element rows is not limited to two or three and the present invention is applied in the same manner regardless of the number of rows in the sub-scanning direction of heat element rows such as the heat element rows Ha, Hb, Hc, and the like. This makes it possible to improve “contact”.

It should be understood by those skilled in the art that various modifications, combinations, sub-combinations, and alterations may occur depending on design requirements and other factors insofar as they are within the scope of the appended claims or the equivalents thereof.

What is claimed is:

1. A thermal head comprising:
a heat generating element row in which plural heat generating elements are arrayed in a main scanning direction; and
a glaze that stores heat generated from the respective heat generating elements,
the thermal head recording an image on a recording medium by causing the respective heat generating elements to generate heat while conveying the recording medium in a sub-scanning direction, wherein
a plurality of the heat generating element rows are arrayed in the sub-scanning direction,
the glaze includes plural convex portions arranged in the sub-scanning direction in association with the number of arrays of the heat generating element rows, and
the heat generating elements are arranged on upper sides of the convex portions, respectively.

2. A thermal head according to claim 1, wherein
the glaze includes ridge portions of a ridge shape in sections thereof in the sub-scanning direction, and
the convex portions are formed on upper sides of the ridge portions, respectively.

3. A thermal head according to claim 2, wherein
the ridge portions are semicircular in the sections in the sub-scanning direction.

4. A thermal head according to claim 2, wherein
the ridge portions are trapezoidal in the sections in the sub-scanning direction.

5. A thermal head according to claim 1, wherein
the glaze is partially divided in the sub-scanning direction in association with a number of arrays of the heat generating element rows and includes plural partial ridge portions of a ridge shape in sections thereof in the sub-scanning direction, and
the convex portions are arranged on upper sides of the partial ridge portions, respectively.

6. A thermal head according to claim 1, wherein
the heat generating elements are connected to electrodes at both ends thereof, respectively, and
respective electrode connecting portions opposed to each other in the sub-scanning direction of the respective heat generating elements are located in positions lower than highest portions of the respective heat generating elements.

7. A thermal head according to claim 6, wherein at least the respective electrode connecting portions are embedded in the glaze.

8. A thermal head comprising:
a heat generating element row in which plural heat generating elements are arrayed in a main scanning direction; and
a glaze that stores heat generated from the respective heat generating elements,
the thermal head recording an image on a recording medium by causing the respective heat generating elements to generate heat while conveying the recording medium in a sub-scanning direction, wherein
a plurality of the heat generating element rows are arrayed in the sub-scanning direction,
the glaze is partially divided in the sub-scanning direction in association with a number of arrays of the heat generating element rows and includes plural partial ridge portions of a ridge shape in sections thereof in the sub-scanning direction, and
the heat generating elements are arranged on upper sides of the partial ridge portions, respectively.

9. A thermal head comprising:
a heat generating element row in which plural heat generating elements are arrayed in a main scanning direction; and
a glaze that stores heat generated from the respective heat generating elements,
the thermal head recording an image on a recording medium by causing the respective heat generating elements to generate heat while conveying the recording medium in a sub-scanning direction, wherein
a plurality of the heat generating element rows are arrayed in the sub-scanning direction,
the glaze includes a ridge portion of a ridge shape in a section thereof in the sub-scanning direction and a flat portion formed at a top of the ridge portion, and
the heat generating elements are arranged on an upper side of the flat portion in each of the heat generating element rows.

10. A thermal head comprising:
a heat generating element row in which plural heat generating elements are arrayed in a main scanning direction; and
a glaze that stores heat generated from the respective heat generating elements,
the thermal head recording an image on a recording medium by causing the respective heat generating elements to generate heat while conveying the recording medium in a sub-scanning direction, wherein
a plurality of the heat generating element rows are arrayed in the sub-scanning direction,
the glaze includes plural ridge portions of a ridge shape in sections thereof in the sub-scanning direction arranged in the sub-scanning direction in association with a number of arrays of the heat generating element rows, and
the heat generating elements are arranged on upper sides of the ridge portions, respectively.

11. A thermal head according to claim 10, wherein at least heat generating elements arranged on the ridge portions at both ends are located to be shifted closer to a center between the ridge portions in the sub-scanning direction than tops of the ridge portions.

12. A thermal head according to claim 10, wherein the respective ridge portions have different heights according to an outer diameter of a platen roller opposed to the ridge portions.

13. A thermal head according to claim 10, wherein
the glaze has a flat base portion and an inclined portion inclined according to an outer diameter of a platen roller opposed to the glaze, and
the respective ridge portions are separately located on upper sides of the base portion and the inclined portion.

14. A thermal head comprising:
a heat generating element row in which plural heat generating elements are arrayed in a main scanning direction; and
a glaze that stores heat generated from the respective heat generating elements,
the thermal head recording an image on a recording medium by causing the respective heat generating elements to generate heat while conveying the recording medium in a sub-scanning direction, wherein
a plurality of the heat generating element rows are arrayed in the sub-scanning direction,
the glaze includes a flat base portion and a ridge portion of a ridge shape in a section thereof in the sub-scanning direction, and
the heat generating elements are separately arranged on upper sides of the base portion and the ridge portion in each of the heat generating element rows.

15. A method of manufacturing a thermal head including a heat generating element row in which plural heat generating elements are arrayed in a main scanning direction and a glaze that stores heat generated from the respective heat generating elements, the thermal head recording an image on a recording medium by causing the respective heat generating elements to generate heat while conveying the recording medium in a sub-scanning direction, the method comprising the steps of:
forming, on a substrate, the glaze having irregularities corresponding to a number of arrays of a plurality of the heat generating element rows arrayed in the sub-scanning direction;
forming, on the irregularities of the glaze, the respective heat generating elements and electrodes for driving the respective heat generating elements; and
coating the respective heat generating elements and the respective electrodes with a protective film.

16. A method of manufacturing a thermal head according to claim 15, wherein the step of forming a glaze is performed by any one or more of a cutting method, an etching method, a printing method, and a removing method.

17. A method of manufacturing a thermal head according to claim 15, further comprising the step of smoothing a surface of the glaze after the step of forming a glaze and before the step of forming the heat generating elements and electrodes.

18. A method of manufacturing a thermal head according to claim 15, further comprising the step of making the irregularities of the glaze gentle with heat treatment after the step of forming the glaze and before the step of forming the heat generating elements and electrodes.

19. A method of manufacturing a thermal head according to claim 15, further comprising the step of polishing a step of the protective film to be gentle after the step of forming a protective film.
